(19) United States
(12) Patent Application Publication
(10) Pub. No.: US 2026/0291565 A1
(43) Pub. Date: Sep. 24, 2026

(54) SYSTEMS AND METHODS FOR VARIABLE CODE-RATE CODING

(71) Applicant: QUALCOMM Incorporated, San Diego, CA (US)

(72) Inventors: Akash Sandeep DOSHI, San Diego, CA (US); Wei YANG, San Diego, CA (US); June NAMGOONG, San Diego, CA (US); Jing JIANG, San Diego, CA (US); Taesang YOO, San Diego, CA (US)

(21) Appl. No.: 19/085,028

(22) Filed: Mar. 20, 2025

(51) Int. Cl. H04B 7/0456

(52) U.S. Cl. CPC H04B 7/0482

(57) ABSTRACT

Various aspects of the present disclosure generally relate to wireless communication, and to variable code-rate coding. For example, one or more techniques are provided for artificial intelligence or machine learning (AI/ML)-based channel coding in which a number of information bits k to be coded is different than a maximum number of information bits kₘₐₓ that an AI/ML model is trained to receive, and/or in which a number of coded symbols n for a codeword is different than a maximum number of coded symbols nₘₐₓ that the AI/ML model is trained to output. In some aspects, multiple output tokens output by the AI/ML-based channel coding (or a modified version of the multiple output tokens) are permutation equivariant relative to multiple input tokens provided as an input to the AI/ML-based channel coding.

### FIELD OF THE DISCLOSURE

Aspects of the present disclosure relate generally to wireless communication systems, and more particularly, to variable code-rate coding in wireless communication systems, such as variable code-rate coding for supporting varying values of information bits, varying values of coded symbols, or both.

### BACKGROUND

Wireless communications systems are widely deployed to provide various types of services such as voice, video, packet data, messaging, broadcast, and other types of traffic. The services may include unicast, multicast, and/or broadcast services, among other examples. Typical wireless communication systems may support multiple-access radio access technologies and include a number of base stations or network nodes, each supporting communication for multiple communication devices, which may be otherwise known as user equipment (UE). These systems may be capable of supporting communication with multiple users by sharing available system resources (such as time domain resources, frequency domain resources, spatial domain resources, and device transmit power, among other examples). These systems may employ multiple-access technologies such as code division multiple access (CDMA) technology, time division multiple access (TDMA) technology, frequency division multiple access (FDMA) technology, orthogonal frequency division multiple access (OFDMA) technology, discrete Fourier transform spread orthogonal frequency division multiplexing (DFT-S-OFDM) technology, single-carrier frequency division multiple access (SC-FDMA) technology, and time division synchronous code division multiple access (TD-SCDMA) technology.

The above multiple-access technologies have been adopted in various telecommunication standards to provide common protocols that enable different wireless communication devices to communicate on a municipal, national, regional, or global level. An example telecommunication standard is New Radio (NR). NR, which may also be referred to as 5G, is part of a continuous mobile broadband evolution promulgated by the Third Generation Partnership Project (3GPP). NR (and other mobile broadband evolutions beyond NR) may be designed to better support Internet of things (IoT) and reduced capability device deployments, industrial connectivity, millimeter wave (mmWave) expansion, licensed and unlicensed spectrum access, non-terrestrial network (NTN) deployment, sidelink and other device-to-device direct communication technologies (for example, cellular vehicle-to-everything (CV2X) communication), massive multiple-input multiple-output (MIMO), disaggregated network architectures and network topology expansions, multiple-subscriber implementations, carrier aggregation, high-precision positioning, and/or radio frequency (RF) sensing, among other examples. As the demand for mobile broadband access continues to increase, further improvements in NR may be implemented, and other radio access technologies, such as 6G, may be introduced to further advance mobile broadband evolution.

A communication system (such as NR, 6G, WiFi, Ethernet, or the like) may use channel coding for communications, such as wireless communications. Channel coding or channel codes generally refer to techniques to encode an input message, such as a data message, to generate an output codeword. Different types of channel coding may provide different benefits, such as data compression or error control. Conventional channel codes are typically linear codes that are configured to use rate matching techniques, such as shortening or puncturing. In some examples, channel coding may be performed using an artificial intelligence or machine learning (AI/ML) model, such as a fully AI/ML generated channel code, or AI/ML augmented classical channel codes (AI/ML augmented Turbo codes, polar codes, Reed Muller codes, etc.).

### SUMMARY

The following summarizes some aspects of the present disclosure to provide a basic understanding of the discussed technology. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

Some aspects described herein relate to a wireless communication device for wireless communication. The wireless communication device includes a processing system that includes one or more processors and one or more memories that store code and are coupled with the one or more processors. The processing system is configured to cause the wireless communication device to obtain a message vector including multiple bits, and generate multiple input tokens in accordance with the message vector. Each of one or more input tokens of the multiple input tokens includes at least one respective bit of the multiple bits. The processing system is also configured to cause the wireless communication device to generate, in accordance with the multiple input tokens and using an artificial neural network, multiple output tokens. The multiple output tokens are permutation equivariant relative to the multiple input tokens. The processing system is further configured to cause the wireless communication device to transmit a codeword vector generated in accordance with the multiple output tokens.

Some aspects described herein relate to a method of wireless communication performed by a wireless communication device. The method includes obtaining a message vector including multiple bits, and generating multiple input tokens in accordance with the message vector. Each of one or more input tokens of the multiple input tokens includes at least one respective bit of the multiple bits. The method also includes generating, in accordance with the multiple input tokens and using an artificial neural network, multiple output tokens. The multiple output tokens are permutation equivariant relative to the multiple input tokens. The method further includes transmitting a codeword vector generated in accordance with the multiple output tokens.

Some aspects described herein relate to an apparatus. The apparatus includes means for obtaining a message vector including multiple bits, and means for generating multiple input tokens in accordance with the message vector. Each of one or more input tokens of the multiple input tokens includes at least one respective bit of the multiple bits. The apparatus also includes means for generating, in accordance with the multiple input tokens and using an artificial neural network, multiple output tokens. The multiple output tokens are permutation equivariant relative to the multiple input tokens. The apparatus further includes means for transmitting a codeword vector generated in accordance with the multiple output tokens.

Some aspects described herein relate to a non-transitory computer-readable medium that stores code that, when executed by one or more processors, cause the one or more processors to perform operations. The operations include obtaining a message vector including multiple bits, and generating multiple input tokens in accordance with the message vector. Each of one or more input tokens of the multiple input tokens includes at least one respective bit of the multiple bits. The operations also include generating, in accordance with the multiple input tokens and using an artificial neural network, multiple output tokens. The multiple output tokens are permutation equivariant relative to the multiple input tokens. The operations further include transmitting a codeword vector generated in accordance with the multiple output tokens.

Some aspects described herein relate to a wireless communication device for wireless communication. The wireless communication device includes a processing system that includes one or more processors and one or more memories that store code and are coupled with the one or more processors. The processing system is configured to cause the wireless communication device to obtain a message vector including multiple bits, generate multiple input tokens in accordance with the message vector, and generate, in accordance with the multiple input tokens and using an artificial neural network, multiple output tokens. The processing system is also configured to cause the wireless communication device to modify the multiple output tokens to include a total number of symbols that is the same as a total number of symbols of a codeword vector. The modified multiple output tokens are permutation equivariant relative to the multiple input tokens. The processing system is further configured to cause the wireless communication device to generate the codeword vector in accordance with the modified multiple output tokens, and transmit the codeword vector.

Some aspects described herein relate to a method of wireless communication performed by a wireless communication device. The method includes obtaining a message vector including multiple bits, generating multiple input tokens in accordance with the message vector, and generating, in accordance with the multiple input tokens and using an artificial neural network, multiple output tokens. The method also includes modifying the multiple output tokens to include a total number of symbols that is the same as a total number of symbols of a codeword vector. The modified multiple output tokens are permutation equivariant relative to the multiple input tokens. The method further includes generating the codeword vector in accordance with the modified multiple output tokens, and transmitting the codeword vector.

Some aspects described herein relate to an apparatus. The apparatus includes means for obtaining a message vector including multiple bits, means for generating multiple input tokens in accordance with the message vector, and means for generating, in accordance with the multiple input tokens and using an artificial neural network, multiple output tokens. The apparatus also includes means for modifying the multiple output tokens to include a total number of symbols that is the same as a total number of symbols of a codeword vector. The modified multiple output tokens are permutation equivariant relative to the multiple input tokens. The apparatus further includes means for generating the codeword vector in accordance with the modified multiple output tokens, and means for transmitting the codeword vector.

Some aspects described herein relate to a non-transitory computer-readable medium that stores instructions that, when executed by one or more processors, cause the one or more processors to perform operations. The operations include obtaining a message vector including multiple bits, generating multiple input tokens in accordance with the message vector, and generating, in accordance with the multiple input tokens and using an artificial neural network, multiple output tokens. The operations also includes modifying the multiple output tokens to include a total number of symbols that is the same as a total number of symbols of a codeword vector. The modified multiple output tokens are permutation equivariant relative to the multiple input tokens. The operations further includes generating the codeword vector in accordance with the modified multiple output tokens, and transmitting the codeword vector.

Some aspects described herein relate to a wireless communication device for wireless communication. The wireless communication device includes a processing system that includes one or more processors and one or more memories that store code and are coupled with the one or more processors. The processing system is configured to cause the wireless communication device to obtain a message vector including multiple bits, and generate multiple input tokens in accordance with the message vector. Each of one or more input token of the multiple input tokens includes at least one respective bit of the multiple bits. The processing system is also configured to cause the wireless communication device to generate, in accordance with the multiple input tokens and using an artificial neural network, multiple output tokens. The processing system is further configured to cause the wireless communication device to modify the multiple output tokens to include a total number of symbols that is the same number as a total number of symbols of a codeword vector. The modified multiple output tokens are permutation equivariant relative to the multiple input tokens. The processing system is configured to cause the wireless communication device to generate the codeword vector in accordance with the modified multiple output tokens, and transmit the codeword vector.

Some aspects described herein relate to a method of wireless communication performed by a wireless communication device. The method includes obtaining a message vector including multiple bits, and generating multiple input tokens in accordance with the message vector. Each of one or more input token of the multiple input tokens includes at least one respective bit of the multiple bits. The method also includes generating, in accordance with the multiple input tokens and using an artificial neural network, multiple output tokens. The method further includes modifying the multiple output tokens to include a total number of symbols that is the same number as a total number of symbols of a codeword vector. The modified multiple output tokens are permutation equivariant relative to the multiple input tokens. The method includes generating the codeword vector in accordance with the modified multiple output tokens, and transmitting the codeword vector.

Some aspects described herein relate to an apparatus. The apparatus includes means for obtaining a message vector including multiple bits, and means for generating multiple input tokens in accordance with the message vector. Each of one or more input token of the multiple input tokens includes at least one respective bit of the multiple bits. The apparatus also includes means for generating, in accordance with the multiple input tokens and using an artificial neural network, multiple output tokens. The apparatus further includes means for modifying the multiple output tokens to include a total number of symbols that is the same number as a total number of symbols of a codeword vector. The modified multiple output tokens are permutation equivariant relative to the multiple input tokens. The apparatus includes means for generating the codeword vector in accordance with the modified multiple output tokens, and means for transmitting the codeword vector.

Some aspects described herein relate to a non-transitory computer-readable medium that stores instructions that, when executed by one or more processors, cause the one or more processors to perform operations. The operations include obtaining a message vector including multiple bits, and generating multiple input tokens in accordance with the message vector. Each of one or more input token of the multiple input tokens includes at least one respective bit of the multiple bits. The operations also includes generating, in accordance with the multiple input tokens and using an artificial neural network, multiple output tokens. The operations further includes modifying the multiple output tokens to include a total number of symbols that is the same number as a total number of symbols of a codeword vector. The modified multiple output tokens are permutation equivariant relative to the multiple input tokens. The operations includes generating the codeword vector in accordance with the modified multiple output tokens, and transmitting the codeword vector.

Aspects of the present disclosure may generally be implemented by or as a method, apparatus, system, computer program product, non-transitory computer-readable medium, user equipment, base station, network node, network entity, wireless communication device, and/or processing system as substantially described with reference to, and as illustrated by, the specification and accompanying drawings.

Other aspects, features, and implementations of the present disclosure will become apparent to a person having ordinary skill in the art, upon reviewing the following description of specific, example implementations of the present disclosure in conjunction with the accompanying figures. While features of the present disclosure may be described relative to particular implementations and figures below, all implementations of the present disclosure can include one or more of the advantageous features described herein. In other words, while one or more implementations may be described as having particular advantageous features, one or more of such features may also be used in accordance with the various implementations of the disclosure described herein. In similar fashion, while example implementations may be described below as device, system, or method implementations, such example implementations can be implemented in various devices, systems, methods, and computer-readable media.

### BRIEF DESCRIPTION OF THE DRAWINGS

A further understanding of the nature and advantages of the present disclosure may be realized by reference to the following drawings. In the appended figures, similar components or features may have the same reference label and designations. Further, various components of the same type may be distinguished by following the reference label by a dash and a second label that distinguishes among the similar components, or by following the reference label with a letter. If just the first reference label is used in the specification, the description is applicable to any one of the similar components having the same first reference label irrespective of the second reference label or letter.

FIG. 1 is a block diagram illustrating details of an example wireless communication network in accordance with the present disclosure.

FIG. 2 is a block diagram illustrating examples of a network node and a user equipment (UE) in accordance with the present disclosure.

FIG. 3 is a block diagram illustrating an example disaggregated base station architecture in accordance with the present disclosure.

FIG. 4 is a block diagram illustrating an example of a wireless communication system that supports variable code-rate coding in accordance with the present disclosure.

FIG. 5 is a diagram illustrating an example of permutation equivariance in accordance with the present disclosure.

FIG. 6 is a diagram illustrating an example of channel coding using an artificial intelligence or machine learning model in accordance with the present disclosure.

FIG. 7 is a diagram illustrating examples of generation of input tokens in accordance with the present disclosure.

FIG. 8 is a diagram illustrating examples of generation of a codeword in accordance with the present disclosure.

FIG. 9 is a flow diagram illustrating an example process that supports variable code-rate coding in accordance with the present disclosure.

FIG. 10 is a flow diagram illustrating an example process that supports variable code-rate coding in accordance with the present disclosure.

FIG. 11 is a flow diagram illustrating an example process that supports variable code-rate coding in accordance with the present disclosure.

FIG. 12 is a block diagram of an example user equipment (UE) that supports variable code-rate coding in accordance with the present disclosure.

### DETAILED DESCRIPTION

Various aspects of the disclosure are described more fully hereinafter with reference to the accompanying drawings. This disclosure may, however, be embodied in many different forms and is not to be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art may appreciate that the scope of the disclosure is intended to cover any aspect of the disclosure disclosed herein, whether implemented independently of or combined with any other aspect of the disclosure. For example, an apparatus may be implemented or a method may be practiced using any quantity of the aspects set forth herein. In addition, the scope of the disclosure is intended to cover such an apparatus or method which is practiced using other structure, functionality, or structure and functionality in addition to or other than the various aspects of the disclosure set forth herein. Any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, or algorithms (collectively referred to as “elements”). These elements may be implemented using hardware, software, or a combination of hardware and software. Whether such elements are implemented as hardware or software depends upon the particular application and design constraints imposed on the overall system.

Channel coding may provide various benefits in a wireless communication system, such as error correction, power reduction, improved reliability, or the like. A channel code can be implemented as a mapping between input values (referred to as message vectors) and output values (referred to as codewords or codeword vectors). For example, a transmitter may obtain a message vector and may refer to a table that maps the message vector and a corresponding codeword vector. The transmitter may transmit a communication carrying or otherwise based on the codeword vector.

According to various embodiments, an artificial intelligence or machine learning (AI/ML) model may be used to perform channel coding. For example, the AI/ML model may receive a message vector as input and may output a corresponding codeword. As another example, the AI/ML model may define mappings between message vectors and corresponding codeword vectors, such that a table can be defined according to these mappings. An AI/ML-based channel code resulting from an AI/ML model that is trained to a sufficient accuracy may provide performance advantages over some other forms of channel codes such as greater flexibility for encoding as compared with codebooks for linear codes, which can improve quality, reliability, and/or throughput.

Many AI/ML channel codes are non-linear. Linearity/non-linearity is a property that generally relates to the structure of a code, such as a channel code. In particular, a linear code may be defined over a finite field Σ. A code C is linear if the code C, for n uses of the channel (Σⁿ), is a subspace of Σⁿ (in other words, C⊂Σⁿ). Thus, any codeword of the code C can be expressed as a linear combination of basis vectors of the subspace C, where the rows of a generator matrix of dimension k×n (where k is the dimension of the subspace) comprise the basis vectors for the code C, and where any linear combination of codewords is also a codeword. Thus, in a linear code, the generator matrix may provide structured encoding. In practical terms, a linear code has structure that can be exploited at the receiver/decoder to provide decoding. Linear codes may also be associated with an equal error probability for each codeword/payload as a property of linearity.

Many non-linear codes may not have such structure, and may not have equal error probability for each codeword/payload. Thus, non-linear codes present certain challenges at the receiver. In particular, in the codebook for a non-linear code (that is, the set of codewords belonging to the nonlinear code), the mapping of messages to the corresponding codewords can be arbitrary. Thus, identifying a structure of the codebook may be difficult, or no structure may be present or exploitable in the codebook. This may lead to a situation where the entire codebook and message-to-codeword mapping is explicitly defined (rather than defined, for example, in terms of a structural representation such as a generator matrix), which can reduce efficiency of encoding and decoding as compared to linear codes.

To enable the channel codes that use the AI/ML model to be linear, one or more constraints or parameters may be applied in relation to the AI/ML model. For example, the one or more constraints or parameters may be associated with a permutation equivariance property (a permutation equivariant function structure) which enables a codebook to be fully determinable using sub-vectors of a generated codeword, and which reduces a size of a look-up table used to store the codebook. The AI/ML model (having the one or more constraints or parameters) is typically trained to receive a maximum number of information bits and to output a maximum number of coded symbols such that the AI/ML model satisfies the permutation equivariance property. However, using a number of information bits other than the maximum number of information bits, and/or if a number of coded symbols for a codeword is different or varies from the maximum number of coded symbols output by the channel coding using the AI/ML model could change the group size required to achieve the permutation equivariance property and hence the size of a look-up table used to store the codebook.

The present disclosure provides systems, apparatus, methods, and computer-readable media for variable code-rate coding for wireless communication systems. In some aspects, techniques for AI/ML-based channel coding are associated with a number of information bits k to be coded that is different than a maximum number of information bits kₘₐₓ that an AI/ML model is trained to receive. For example, one or more techniques may include obtaining a message vector including multiple bits, such as the number of information bits k, and generating multiple input tokens (having the maximum number of information bits kₘₐₓ) to be provided as an input associated with the AI/ML model. The multiple input tokens may be generated according to a scheme, such as an input token scheme, that indicates how the number of information bits k, and additionally one or more padding zeros, are to be allocated or distributed among the multiple input tokens such that the multiple input tokens are permutation equivariant relative to multiple output tokens generated using the AI/ML model. For example, a first input token scheme may indicate to append one or more padding zeros to the number of information bits k and to distribute the combination of the information bits and the one or more zeros among the multiple input tokens. A second input token scheme may indicate to distribute the information bits equally among the multiple input tokens and to set any remaining bits of each of the multiple input tokens to zero. A third input token scheme may indicate, when the number of information bits k is not a multiple of the number of the multiple input tokens, to allocate a first number of the information bits to one or more first input tokens of the multiple input tokens, and to allocate a second number of information bits to one or more second input tokens of the multiple input tokens. The third input token scheme may also indicate which input tokens of the multiple input tokes are included in the one or more first input tokens and/or the one or more second input tokens.

In some aspects, techniques for AI/ML-based channel coding are associated with a number of coded symbols n for a codeword that is different or varies from a maximum number of coded symbols nₘₐₓ output by the channel coding in accordance with the AI/ML model. For example, the one or more techniques may include obtaining multiple output tokens (having a maximum number of coded symbols nₘₐₓ) and generating modified multiple output tokens that have a number of coded symbols n to enable generation of the codeword from the modified multiple output tokens. The modified multiple output tokens may be generated according to a scheme, such as an output token scheme, that indicates how at least a portion of a maximum number of coded symbols nₘₐₓ are to be selected to form the modified multiple output tokens such that the modified multiple output tokens are permutation equivariant relative to the multiple input tokens. For example, a first output token scheme may indicate to remove one or more coded symbols from the end of the multiple output tokens, collectively, to generate the modified multiple output tokens. As another example, a second output token scheme may indicate to retain the same number of one or more coded symbols from end of each output token of the multiple output tokens and drop the remaining unretained coded symbols. A third output token scheme may indicate, when the number of coded symbols n for a codeword is not a multiple of the total number of the multiple output tokens, to remove a first number of the coded symbols from one or more first output tokens of the multiple output tokens, and remove a second number of coded symbols from one or more second output tokens of the multiple output tokens. The third output token scheme may also indicate which output tokens of the multiple output tokes are included in the one or more first output tokens and/or the one or more second output tokens.

Particular implementations of the subject matter described in this disclosure can be implemented to realize one or more of the following potential advantages. In some aspects, generation of the multiple input tokens when the number of information bits is different than the maximum number of information bits, and/or generation of the modified multiple output tokens when the number of coded symbols for the codeword is different than the maximum number of coded, maintains the group size required to achieve the permutation equivariance property. Additionally, by providing the multiple output tokens or the modified multiple output tokens that are permutation equivariant relative to the multiple input tokens, a size of the table is reduced relative to a table that explicitly defines all possible mappings of message vectors and codeword vectors. The reduced size of the table accordingly has a smaller size and memory footprint as compared to the table that explicitly defines all possible mappings of message vectors and codeword vectors.

In some aspects, use of the first input token scheme provides a low-complexity technique to generate the multiple input tokens. In some other aspects, use of either of the second input token scheme or the third input token scheme ensures that two or more input tokens of the multiple input tokens are not the same, such as by each of the two or more input tokens having all zeros, and thereby promotes token distinctiveness across codewords and increases the pairwise distance among codewords. In some other aspects, the third input token scheme may specify generation of the multiple input tokens when the number of information bits k is not a multiple of the number of the multiple input tokens, and may provide a more complex technique as compared to the first and second input token schemes.

In some aspects, use of the first output token scheme provides a low-complexity technique to generate the multiple modified output tokens. In some other aspects, use of either of the second output token scheme or the third output token scheme ensures that the multiple modified output tokens are group permutation symmetric. In some other aspects, the third output token scheme may specify generation of the multiple modified output tokens when the number of coded symbols n for the codeword is not a multiple of the total number of the multiple output tokens, and may provide a more complex technique as compared to the first and second output token schemes.

This disclosure relates generally to providing or participating in authorized shared access between two or more wireless communications systems, also referred to as wireless communications networks. In various implementations, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, long term evolution (LTE) networks, Global System for Mobile Communications (GSM) networks, 5th Generation (5G) or new radio (NR) networks (sometimes referred to as “5G NR” networks, systems, or devices), as well as other communications networks. As described herein, the terms “networks” and “systems” may be used interchangeably.

Multiple-access radio access technologies (RATs) have been adopted in various telecommunication standards to provide common protocols that enable wireless communication devices to communicate on a municipal, enterprise, national, regional, or global level. For example, 5G New Radio (NR) is part of a continuous mobile broadband evolution promulgated by the Third Generation Partnership Project (3GPP). 5G NR supports various technologies and use cases including enhanced mobile broadband (eMBB), ultra-reliable low-latency communication (URLLC), massive machine-type communication (mMTC), millimeter wave (mmWave) technology, beamforming, network slicing, edge computing, Internet of Things (IoT) connectivity and management, and network function virtualization (NFV). 5G NR networks contemplate diverse deployments, diverse spectrum, and diverse services and devices that may be implemented using an OFDM-based unified, air interface.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) or frequency division duplex (FDD) design; and advanced wireless technologies, such as massive multiple input, multiple output (MIMO), robust mm Wave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 gigahertz (GHz) FDD or TDD implementations, subcarrier spacing may occur with 15 kilohertz (kHz), for example over 1, 5, 10, 20 megahertz (MHz), and the like bandwidth. For other various outdoor and small cell coverage deployments of TDD greater than 3 GHz, subcarrier spacing may occur with 30 kHz over 80 or 100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

As the demand for broadband access increases and as technologies supported by wireless communication networks evolve, further technological improvements may be adopted in or implemented for 5G NR or future RATs, such as 6G, to further advance the evolution of wireless communication for a wide variety of existing and new use cases and applications. Such technological improvements may be associated with new frequency band expansion, licensed and unlicensed spectrum access, overlapping spectrum use, small cell deployments, non-terrestrial network (NTN) deployments, disaggregated network architectures and network topology expansion, device aggregation, advanced duplex communication, sidelink and other device-to-device direct communication, IoT (including passive or ambient IoT) networks, reduced capability (RedCap) UE functionality, industrial connectivity, multiple-subscriber implementations, high-precision positioning, radio frequency (RF) sensing, and/or artificial intelligence or machine learning (AI/ML), among other examples. These technological improvements may support use cases such as wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial and/or aerial platforms, among other examples. The methods, operations, apparatuses, and techniques described herein may enable one or more of the foregoing technologies and/or support one or more of the foregoing use cases. For clarity, certain aspects of the present disclosure may be described below with reference to example 5G NR implementations or in a 5G-centric way, and 5G terminology may be used as illustrative examples in portions of the description below; however, the description is not intended to be limited to 5G applications.

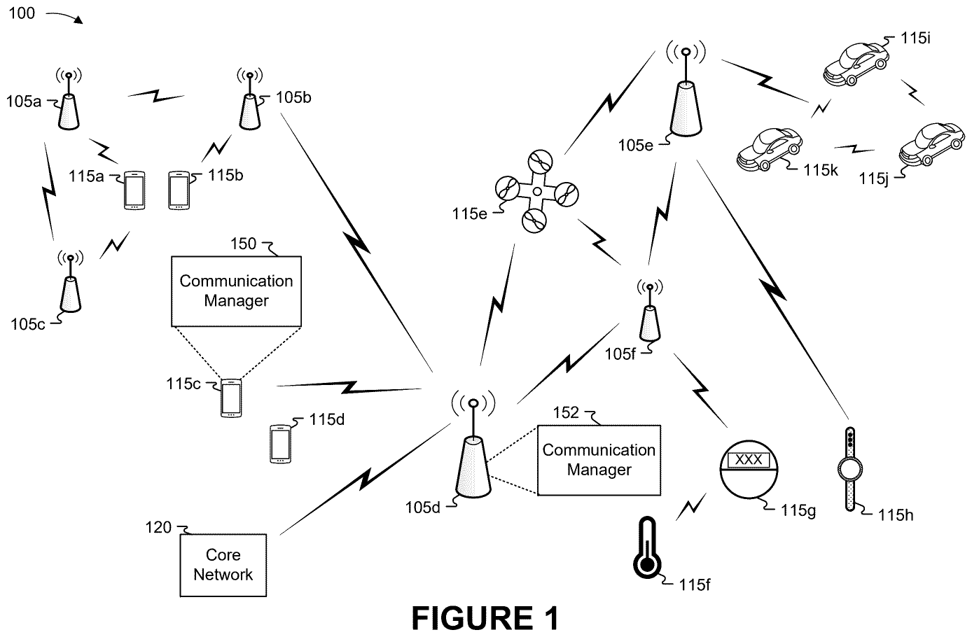

FIG. 1 is a block diagram illustrating details of an example wireless communication network 100 in accordance with the present disclosure. The wireless communication network 100 may, for example, be or include elements of a 5G (or NR) network or a 6G network, among other examples. As appreciated by those skilled in the art, components appearing in FIG. 1 are likely to have related counterparts in other network arrangements including, for example, cellular-style network arrangements and non-cellular-style-network arrangements, such as device-to-device, peer-to-peer, or ad hoc network arrangements, among other examples.

The wireless communication network 100 illustrated in FIG. 1 includes multiple network nodes 105, also referred to as network entities, and multiple user equipments (UEs) 115. A network node may be a station that communicates with UEs and may be referred to as a base station, an evolved node B (eNB), a next generation eNB (gNB), an access point, and the like. Each network node 105 may provide communication coverage for a particular geographic area. In 3GPP, the term “cell” can refer to this particular geographic coverage area of a network node or a network node subsystem serving the coverage area, depending on the context in which the term is used. In implementations of the wireless communication network 100 herein, the network nodes 105 may be associated with a same operator or different operators, such as the wireless communication network 100 may include a plurality of operator wireless networks. In some examples, an individual network node 105 or UE 115 may be operated by more than one network operating entity. In some other examples, each network node 105 and UE 115 may be operated by a single network operating entity.

The network nodes 105 and the UEs 115 of the wireless communication network 100 may communicate using the electromagnetic spectrum, which may be subdivided by frequency or wavelength into various classes, bands, carriers, and/or channels. For example, devices of the wireless communication network 100 may communicate using one or more operating bands. In some aspects, multiple wireless communication networks 100 may be deployed in a given geographic area. Each wireless communication network 100 may support a particular RAT (which may also be referred to as an air interface) and may operate on one or more carrier frequencies in one or more frequency ranges. Examples of RATs include a 4G RAT, a 5G/NR RAT, and/or a 6G RAT, among other examples. In some examples, when multiple RATs are deployed in a given geographic area, each RAT in the geographic area may operate on different frequencies to avoid interference with one another.

Various operating bands have been defined as frequency range designations FR1 (410 MHz through 7.125 GHz), FR2 (24.25 GHz through 52.6 GHz), FR3 (7.125 GHz through 24.25 GHz), FR4a or FR4-1 (52.6 GHz through 71 GHz), FR4 (52.6 GHz through 114.25 GHz), and FR5 (114.25 GHz through 300 GHz). Although a portion of FR1 is greater than 6 GHz, FR1 is often referred to (interchangeably) as a “Sub-6 GHz” band in some documents and articles. Similarly, FR2 is often referred to (interchangeably) as a “millimeter wave” band in some documents and articles, despite being different than the extremely high frequency (EHF) band (30 GHz through 300 GHz), which is identified by the International Telecommunications Union (ITU) as a “millimeter wave” band. The frequencies between FR1 and FR2 are often referred to as mid-band frequencies, which include FR3. Frequency bands falling within FR3 may inherit FR1 characteristics or FR2 characteristics, and thus may effectively extend features of FR1 or FR2 into mid-band frequencies. Thus, “sub-6 GHz,” if used herein, may broadly refer to frequencies that are less than 6 GHz, that are within FR1, and/or that are included in mid-band frequencies. Similarly, the term “millimeter wave,” if used herein, may broadly refer to frequencies that are included in mid-band frequencies, that are within FR2, FR4, FR4-a or FR4-1, or FR5, and/or that are within the EHF band. Higher frequency bands may extend 5G NR operation, 6G operation, and/or other RATs beyond 52.6 GHz. For example, each of FR4a, FR4-1, FR4, and FR5 falls within the EHF band. In some examples, the wireless communication network 100 may implement dynamic spectrum sharing (DSS), in which multiple RATs (for example, 4G/LTE and 5G/NR) are implemented with dynamic bandwidth allocation (for example, in accordance with user demand) in a single frequency band. It is contemplated that the frequencies included in these operating bands (for example, FR1, FR2, FR3, FR4, FR4-a, FR4-1, and/or FR5) may be modified, and techniques described herein may be applicable to those modified frequency ranges.

A network node 105 may include one or more devices, components, or systems that enable communication between a UE 115 and one or more devices, components, or systems of the wireless communication network 100. A network node 105 may be, may include, or may also be referred to as an NR network node, a 5G network node, a 6G network node, a Node B, an eNB, a gNB, an access point (AP), a transmission reception point (TRP), a mobility element, a core, a network entity, a network element, a network equipment, and/or another type of device, component, or system included in a radio access network (RAN).

A network node 105 may be implemented as a single physical node (for example, a single physical structure) or may be implemented as two or more physical nodes (for example, two or more distinct physical structures). For example, a network node 105 may be a device or system that implements part of a radio protocol stack, a device or system that implements a full radio protocol stack (such as a full gNB protocol stack), or a collection of devices or systems that collectively implement the full radio protocol stack. For example, and as shown, a network node 105 may be an aggregated network node (having an aggregated architecture), meaning that the network node 105 may implement a full radio protocol stack that is physically and logically integrated within a single node (for example, a single physical structure) in the wireless communication network 100. For example, an aggregated network node 105 may consist of a single standalone base station or a single TRP that uses a full radio protocol stack to enable or facilitate communication between a UE 115 and a core network 120 of the wireless communication network 100.

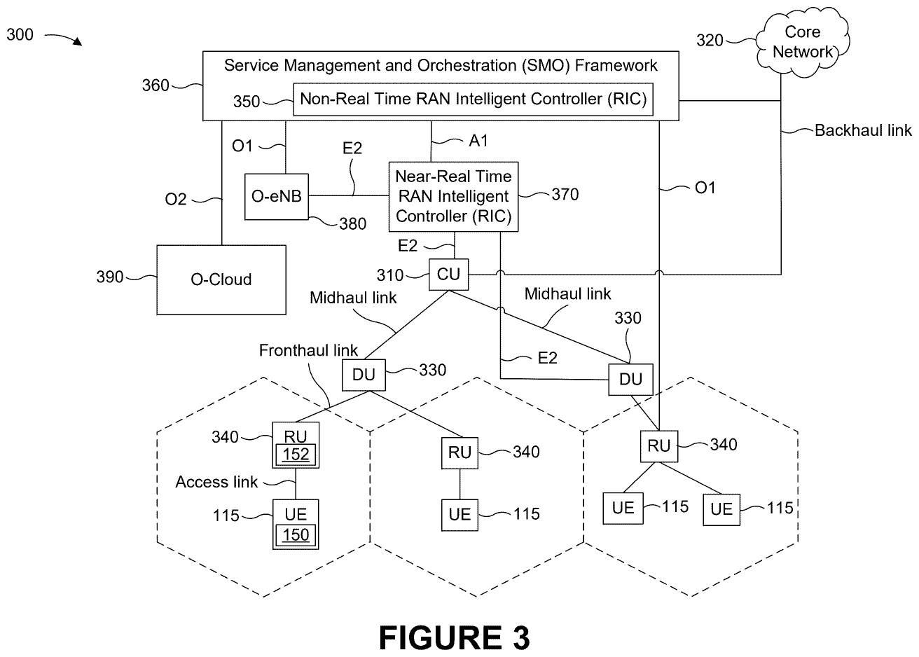

Alternatively, a network node 105 may be a disaggregated network node (sometimes referred to as a disaggregated base station), meaning that the network node 105 may implement a radio protocol stack that is physically distributed and/or logically distributed among two or more nodes in the same geographic location or in different geographic locations. For example, a disaggregated network node may have a disaggregated architecture, as further described herein with reference to FIG. 3. In some deployments, disaggregated network nodes 105 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating base station functionality into multiple units that can be individually deployed.

The network nodes 105 of the wireless communication network 100 may include one or more central units (CUs), one or more distributed units (DUs), and/or one or more radio units (RUs). A CU may host one or more higher layer control functions, such as radio resource control (RRC) functions, packet data convergence protocol (PDCP) functions, and/or service data adaptation protocol (SDAP) functions, among other examples. A DU may host one or more of a radio link control (RLC) layer, a medium access control (MAC) layer, and/or one or more higher physical (PHY) layers depending, at least in part, on a functional split, such as a functional split defined by the 3GPP. In some examples, a DU also may host one or more lower PHY layer functions, such as a fast Fourier transform (FFT), an inverse FFT (iFFT), beamforming, physical random access channel (PRACH) extraction and filtering, and/or scheduling of resources for one or more UEs 115, among other examples. An RU may host RF processing functions or lower PHY layer functions, such as an FFT, an iFFT, beamforming, or PRACH extraction and filtering, among other examples, according to a functional split, such as a lower layer functional split. In such an architecture, each RU can be operated to handle over the air (OTA) communication with one or more UEs 115.

In some aspects, a single network node 105 may include a combination of one or more CUs, one or more DUs, and/or one or more RUs. Additionally, or alternatively, a network node 105 may include one or more Near-Real Time (Near-RT) RAN Intelligent Controllers (RICs) and/or one or more Non-Real Time (Non-RT) RICs. In some examples, a CU, a DU, and/or an RU may be implemented as a virtual unit, such as a virtual central unit (VCU), a virtual distributed unit (VDU), or a virtual radio unit (VRU), among other examples. A virtual unit may be implemented as a virtual network function, such as associated with a cloud deployment.

Some network nodes 105 (for example, a base station, an RU, or a TRP) may provide communication coverage for a particular geographic area. In the 3GPP, the term “cell” can refer to a coverage area of a network node 105 or to a network node 105 itself, depending on the context in which the term is used. A network node 105 may support one or multiple (for example, three) cells. In some examples, a network node 105 may provide communication coverage for a macro cell, a pico cell, a femto cell, or another type of cell. A macro cell may cover a relatively large geographic area (for example, several kilometers in radius) and may allow unrestricted access by UEs 115 with service subscriptions. A pico cell may cover a relatively small geographic area and may allow unrestricted access by UEs 115 with service subscriptions. A femto cell may cover a relatively small geographic area (for example, a home) and may allow restricted access by UEs 115 having association with the femto cell (for example, UEs 115 in a closed subscriber group (CSG)). A network node 105 for a macro cell may be referred to as a macro network node. A network node 105 for a pico cell may be referred to as a pico network node. A network node 105 for a femto cell may be referred to as a femto network node or an in-home network node. In some examples, a cell may not necessarily be stationary. For example, the geographic area of the cell may move according to the location of an associated mobile network node 105 (for example, a train, a satellite base station, an unmanned aerial vehicle, or an NTN network node).

The wireless communication network 100 may be a heterogeneous network that includes network nodes 105 of different types, such as macro network nodes, pico network nodes, femto network nodes, relay network nodes, aggregated network nodes, and/or disaggregated network nodes, among other examples. In the example shown in FIG. 1, network nodes 105d and 105e are regular macro network nodes, while network nodes 105a-105c are macro network nodes enabled with one of 3 dimension (3D), full dimension (FD), or massive MIMO. Network nodes 105a-105c take advantage of their higher dimension MIMO capabilities to exploit 3D beamforming in both elevation and azimuth beamforming to increase coverage and capacity. Network node 105f is a small cell network node which may be a home node or portable access point. A network node may support one or multiple cells, such as two cells, three cells, four cells, and the like. Various different types of network nodes 105 may generally transmit at different power levels, serve different coverage areas, and/or have different impacts on interference in the wireless communication network 100 than other types of network nodes 105. For example, macro network nodes may have a high transmit power level (for example, 5 to 40 watts), whereas pico network nodes, femto network nodes, and relay network nodes may have lower transmit power levels (for example, 0.1 to 2 watts).

In some examples, a network node 105 may be, may include, or may operate as an RU, a TRP, or a base station that communicates with one or more UEs 115 via a radio access link (which may be referred to as a “Uu” link). The radio access link may include a downlink and an uplink. “Downlink” (or “DL”) refers to a communication direction from a network node 105 to a UE 115, and “uplink” (or “UL”) refers to a communication direction from a UE 115 to a network node 105. Downlink channels may include one or more control channels and one or more data channels. A downlink control channel may be used to transmit downlink control information (DCI) (for example, scheduling information, reference signals, and/or configuration information) from a network node 105 to a UE 115. A downlink data channel may be used to transmit downlink data (for example, user data associated with a UE 115) from a network node 105 to a UE 115. Downlink control channels may include one or more physical downlink control channels (PDCCHs), and downlink data channels may include one or more physical downlink shared channels (PDSCHs). Uplink channels may similarly include one or more control channels and one or more data channels. An uplink control channel may be used to transmit uplink control information (UCI) (for example, reference signals and/or feedback corresponding to one or more downlink transmissions) from a UE 115 to a network node 105. An uplink data channel may be used to transmit uplink data (for example, user data associated with a UE 115) from a UE 115 to a network node 105. Uplink control channels may include one or more physical uplink control channels (PUCCHs), and uplink data channels may include one or more physical uplink shared channels (PUSCHs). The downlink and the uplink may each include a set of resources on which the network node 105 and the UE 115 may communicate.

Downlink and uplink resources may include time domain resources (frames, subframes, slots, and/or symbols), frequency domain resources (frequency bands, component carriers, subcarriers, resource blocks, and/or resource elements), and/or spatial domain resources (particular transmit directions and/or beam parameters). Frequency domain resources of some bands may be subdivided into bandwidth parts (BWPs). A BWP may be a continuous block of frequency domain resources (for example, a continuous block of resource blocks) that are allocated for one or more UEs 115. A UE 115 may be configured with both an uplink BWP and a downlink BWP (where the uplink BWP and the downlink BWP may be the same BWP or different BWPs). A BWP may be dynamically configured (for example, by a network node 105 transmitting a DCI configuration to the one or more UEs 115) and/or reconfigured, which means that a BWP can be adjusted in real-time (or near-real-time) in accordance with changing network conditions in the wireless communication network 100 and/or in accordance with the specific requirements of the one or more UEs 115. This enables more efficient use of the available frequency domain resources in the wireless communication network 100 because fewer frequency domain resources may be allocated to a BWP for a UE 115 (which may reduce the quantity of frequency domain resources that a UE 115 is required to monitor), leaving more frequency domain resources to be spread across multiple UEs 115. Thus, BWPs may also assist in the implementation of lower-capability UEs 115 by facilitating the configuration of smaller bandwidths for communication by such UEs 115.

As described above, in some aspects, the wireless communication network 100 may be, may include, or may be included in, an IAB network. In an IAB network, at least one network node 105 is an anchor network node that communicates with the core network 120. An anchor network node 105 may also be referred to as an IAB donor (or “IAB-donor”). The anchor network node 105 may connect to the core network 120 via a wired backhaul link. For example, an Ng interface of the anchor network node 105 may terminate at the core network 120. Additionally, or alternatively, an anchor network node 105 may connect to one or more devices of the core network 120 that provide a core access and mobility management function (AMF). An IAB network also generally includes multiple non-anchor network nodes 105, which may also be referred to as relay network nodes or simply as IAB nodes (or “IAB-nodes”). Each non-anchor network node 105 may communicate directly with the anchor network node 105 via a wireless backhaul link to access the core network 120, or may communicate indirectly with the anchor network node 105 via one or more other non-anchor network nodes 105 and associated wireless backhaul links that form a backhaul path to the core network 120. Some anchor network nodes 105 or other non-anchor network nodes 105 may also communicate directly with one or more UEs 115 via wireless access links that carry access traffic. In some examples, network resources for wireless communication (such as time resources, frequency resources, and/or spatial resources) may be shared between access links and backhaul links.

The wireless communication network 100 may support synchronous or asynchronous operation. For synchronous operation, the network nodes may have similar frame timing, and transmissions from different network nodes may be approximately aligned in time. For asynchronous operation, the network nodes may have different frame timing, and transmissions from different network nodes may not be aligned in time. In some scenarios, networks may be enabled or configured to handle dynamic switching between synchronous or asynchronous operations.

The UEs 115 are physically dispersed throughout the wireless communication network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. Within the present document, a “mobile” apparatus or UE need not necessarily have a capability to move, and may be stationary. Some non-limiting examples of a mobile apparatus, such as may include implementations of one or more of the UEs 115, include a mobile phone, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A UE 115 may additionally be an “Internet of Things” (IoT) or “Internet of Everything” (IoE) device, an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, a gesture tracking device, a medical device, a digital audio player (such as MP3 player), a camera or a game console, among other examples.

The UEs 115 may also include digital home or smart home devices, such as a home audio, video, and multimedia device, an appliance, a sensor, a vending machine, intelligent lighting, a home security system, or a smart meter, among other examples. In one aspect, a UE may be a device that includes a Universal Integrated Circuit Card (UICC). In another aspect, a UE may be a device that does not include a UICC. In some aspects, UEs that do not include UICCs may be referred to as IoE devices. The UEs 115a-115d of the implementation illustrated in FIG. 1 are examples of mobile smart phone-type devices accessing the wireless communication network 100. A UE may be a machine specifically configured for connected communication, including machine type communication (MTC), enhanced MTC (eMTC), narrowband IoT (NB-IoT) and the like. The UEs 115e-115k illustrated in FIG. 1 are examples of various machines configured for communication that access the wireless communication network 100.

A mobile apparatus, such as the UEs 115, may be able to communicate with any type of the network nodes, whether macro network nodes, pico network nodes, femto network nodes, macro base stations, pico base stations, femto base stations, relays, and the like. In FIG. 1, a communication link (represented as a lightning bolt) indicates wireless transmissions between a UE and a serving network node, which is a network node designated to serve the UE on the downlink or uplink, wireless transmissions between network nodes, and backhaul transmissions between network nodes. Backhaul communication between network nodes of the wireless communication network 100 may occur using wired or wireless communication links.

In some examples, two or more UEs 115 (for example, shown as UE 115i and UE 115j) may communicate directly with one another using sidelink communications (for example, without communicating by way of a network node 105 as an intermediary). As an example, the UE 115i may directly transmit data, control information, or other signaling as a sidelink communication to the UE 115j. This is in contrast to, for example, the UE 115i first transmitting data in a UL communication to a network node 105, which then transmits the data to the UE 115j in a DL communication. In various examples, the UEs 115 may transmit and receive sidelink communications using peer-to-peer (P2P) communication protocols, device-to-device (D2D) communication protocols, vehicle-to-everything (V2X) communication protocols (which may include vehicle-to-vehicle (V2V) protocols, vehicle-to-infrastructure (V2I) protocols, and/or vehicle-to-pedestrian (V2P) protocols), and/or mesh network communication protocols. In some deployments and configurations, a network node 105 may schedule and/or allocate resources for sidelink communications between UEs 115 in the wireless communication network 100. In some other deployments and configurations, a UE 115 (instead of a network node 105) may perform, or collaborate or negotiate with one or more other UEs to perform, scheduling operations, resource selection operations, and/or other operations for sidelink communications.

In some examples, the UEs 115 and the network nodes 105 may perform MIMO communication. “MIMO” generally refers to transmitting or receiving multiple signals (such as multiple layers or multiple data streams) simultaneously over the same time and frequency resources. MIMO techniques generally exploit multipath propagation. MIMO may be implemented using various spatial processing or spatial multiplexing operations. In some examples, MIMO may support simultaneous transmission to multiple receivers, referred to as multi-user MIMO (MU-MIMO). Some RATs may employ advanced MIMO techniques, such as mTRP operation (including redundant transmission or reception on multiple TRPs), reciprocity in the time domain or the frequency domain, single-frequency-network (SFN) transmission, or non-coherent joint transmission (NC-JT).

As an example of operation at the wireless communication network 100, the network nodes 105a-105c serve the UEs 115a and 115b using 3D beamforming and coordinated spatial techniques, such as coordinated multipoint (COMP) or multi-connectivity. Macro network node 105d performs backhaul communications with the network nodes 105a-105c, as well as with the small cell network node 105f. Macro network node 105d also transmits multicast services which are subscribed to and received by the UEs 115c and 115d. Such multicast services may include mobile television or streaming video, or may include other services for providing community information, such as weather emergencies or alerts, such as Amber alerts or gray alerts.

The wireless communication network 100 of implementations supports mission critical communications with ultra-reliable and redundant links for mission critical devices, such the UE 115e, which is a drone. Redundant communication links with the UE 115e include communication links from the macro network nodes 105d and 105e, as well as the small cell network node 105f. Other machine type devices, such as UE 115f (thermometer), the UE 115g (smart meter), and the UE 115h (wearable device) may communicate through the wireless communication network 100 either directly with network nodes, such as the small cell network node 105f and the macro network node 105e, or in multi-hop configurations by communicating with another user device which relays its information to the network, such as the UE 115f communicating temperature measurement information to the UE 115g, which is then reported to the network through the small cell network node 105f. The wireless communication network 100 may provide additional network efficiency through dynamic, low-latency TDD or FDD communications, such as in a vehicle-to-vehicle (V2V) mesh network between the UEs 115i-115k communicating with the macro network node 105e.

In some aspects, one or more of the network nodes 105 and one or more of the UEs may perform wireless communications that support variable code-rate coding. For example, one or more of the UEs 115 (such as the UE 115c) may include a communication manager 150 that manages operations that support variable code-rate coding. As another example, one or more of the network nodes 105 (such as the network node 105d) may include a communication manager 152 that manages operations that support variable code-rate coding.

In some aspects, the operations performed by the communication manager 150 or 152 include obtaining a message vector including multiple bits; generating multiple input tokens in accordance with the message vector, each of one or more input tokens of the multiple input tokens includes at least one respective bit of the multiple bits; generating, in accordance with the multiple input tokens and using an artificial neural network (ANN), multiple output tokens, where the multiple output tokens are permutation equivariant relative to the multiple input tokens; and transmitting a codeword or a communication in accordance with the codeword vector, where the codeword vector generated in accordance with the multiple output tokens.

In some other aspects, the operations performed by the communication manager 150 or 152 include obtaining a message vector including multiple bits; generating multiple input tokens in accordance with the message vector; generating, in accordance with the multiple input tokens and using an artificial neural network, multiple output tokens; modifying the multiple output tokens to include a total number of symbols that is the same as a total number of symbols of a codeword vector, where the modified multiple output tokens are permutation equivariant relative to the multiple input tokens; generating the codeword vector in accordance with the modified multiple output tokens; and transmitting the codeword or a communication in accordance with the codeword vector.

In some other aspects, the operations performed by the communication manager 150 or 152 include obtaining a message vector including multiple bits; generating multiple input tokens in accordance with the message vector, where each of one or more input token of the multiple input tokens includes at least one respective bit of the multiple bits; generating, in accordance with the multiple input tokens and using an artificial neural network, multiple output tokens; modifying the multiple output tokens to include a total number of symbols that is the same number as a total number of symbols of a codeword vector, where the modified multiple output tokens are permutation equivariant relative to the multiple input tokens; generating the codeword vector in accordance with the modified multiple output tokens; and transmitting the codeword or a communication in accordance with the codeword vector.

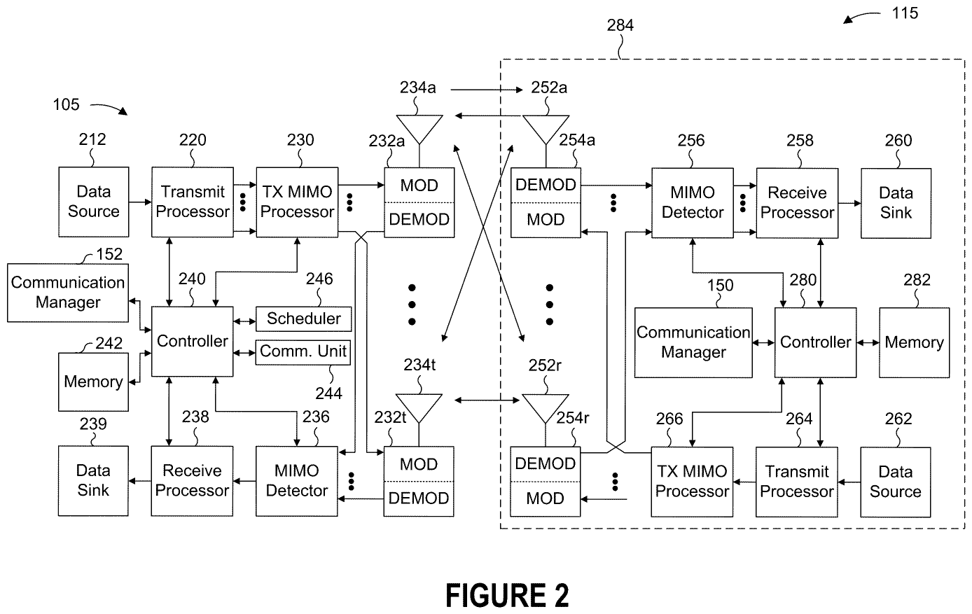

FIG. 2 is a block diagram illustrating examples of a network node 105 and a UE 115 in accordance with the present disclosure. The network node 105 and the UE 115 may be one of the network nodes 105 and one of the UEs 115 in FIG. 1. For a restricted association scenario, the network node 105 may be the small cell network node 105f in FIG. 1, and the UE 115 may be the UE 115c or 115d operating in a service area of the network node 105f, which in order to access the small cell network node 105f, would be included in a list of accessible UEs for the small cell network node 105f. Additionally, the network node 105 may be a base station or network entity of some other type. As shown in FIG. 2, the network node 105 may be equipped with antennas 234a through 234t, and the UE 115 may be equipped with antennas 252a through 252r for facilitating wireless communications.

For downlink communication from the network node 105 to the UE 115, a transmit processor 220 may receive data (“downlink data”) from a data source 212 (such as a data pipeline or a data queue) and control information from a controller 240. The control information may be for the physical broadcast channel (PBCH), physical control format indicator channel (PCFICH), physical hybrid-ARQ (automatic repeat request) indicator channel (PHICH), PDCCH, enhanced physical downlink control channel (EPDCCH), or MTC physical downlink control channel (MPDCCH), among other examples. The data may be for the PDSCH, among other examples. The transmit processor 220 may process, such as encode and symbol map, such as in accordance with a selected modulation and coding scheme (MCS), the data and control information to obtain data symbols and control symbols, respectively. Additionally, the transmit processor 220 may generate reference symbols for reference signals, such as for a cell-specific reference signal (CRS), a demodulation reference signal (DMRS), or a channel state information (CSI) reference signal (CSI-RS) and/or synchronization signals, such as for a primary synchronization signal (PSS) or a secondary synchronization signal (SSS).

Transmit (TX) multiple-input multiple-output (MIMO) processor 230 may perform spatial processing on the data symbols, the control symbols, and/or the reference symbols, if applicable, and may provide output symbol streams to modems 232a through 232t. For example, each output symbol stream may be provided to a respective modulator component (shown as MOD) of a modem 232. In some examples, spatial processing performed on the data symbols, the control symbols, and/or the reference symbols may include precoding. Each modem 232 may use the respective modulator component to process a respective output symbol stream, such as for OFDM, among other examples, to obtain an output sample stream. Each modem 232 may additionally, or alternatively use the respective modulator component to process the output sample stream to obtain a downlink signal. For example, to process the output sample stream, each modem 232 may use the respective modulator component to convert to analog, amplify, filter, and upconvert the output sample stream to obtain the downlink signal. The modems 232a through 232t may together transmit a set of downlink signals from via the antennas 234a through 234t, respectively.

A downlink signal may include a DCI communication, a MAC control element (MAC-CE) communication, an RRC communication, a downlink reference signal, or another type of downlink communication. Downlink signals may be transmitted on a PDCCH, a PDSCH, and/or on another downlink channel. A downlink signal may carry one or more transport blocks (TBs) of data. A TB may be a unit of data that is transmitted over an air interface in the wireless communication network 100. A data stream (for example, from the data source 212) may be encoded into multiple TBs for transmission over the air interface. The quantity of TBs used to carry the data associated with a particular data stream may be associated with a TB size common to the multiple TBs. The TB size may be associated with radio channel conditions of the air interface, the MCS used for encoding the data, the downlink resources allocated for transmitting the data, and/or another parameter. In general, the larger the TB size, the greater the amount of data that can be transmitted in a single transmission, which reduces signaling overhead. However, larger TB sizes may be more prone to transmission and/or reception errors than smaller TB sizes, but such errors may be mitigated by more robust error correction techniques.

At the UE 115, the antennas 252a through 252r may receive the downlink signals from the network node 105 and may provide a set of received signals to modems 254a through 254r. For example, each received signal may be provided to a respective demodulator component (shown as DEMOD) of a modem 254. Each modem 254 may use the respective demodulator component to condition a respective received signal to obtain input samples. For example, to condition the respective received signal, the demodulator component of each modem 254 may filter, amplify, downconvert, and/or digitize the respective received signal to obtain the input samples. Each modem 254 may use the respective demodulator component to further process the input samples, such as for OFDM, among other examples, to obtain received symbols. MIMO detector 256 may obtain received symbols from modems 254a through 254r, perform MIMO detection on the received symbols if applicable, and provide detected symbols. Receive processor 258 may process the detected symbols, provide decoded data for the UE 115 to a data sink 260 (which may include a data pipeline, a data queue, and/or an application executed on the UE 115), and provide decoded control information to a controller 280. For example, to process the detected symbols, the receive processor 258 may demodulate, deinterleave, and decode the detected symbols.

In some aspects, one or a combination of the antenna(s) 252, the modem(s) 254, the MIMO detector 256, the receive processor 258, the transmit processor 264, or the TX MIMO processor 266 may be included in a transceiver that is included in the UE 115. The transceiver may be under control of and used by one or more processors, such as the controller 280, and in some aspects in conjunction with processor-readable code stored in the memory 282, to perform aspects of the methods, processes, or operations described herein. In some aspects, the UE 115 may include another interface, another communication component, and/or another component that facilitates communication with the network node 105 and/or another UE 115. Additionally, or alternatively, one or more of the components of the UE 115 may be included in a housing 284.

For uplink communications from the UE 115 to the network node 105, a transmit processor 264 may receive and process data (“uplink data”) from a data source 262 and control information (such as for the PUCCH) from the controller 280. The control information may include one or more parameters, feedback, one or more signal measurements, and/or other types of control information. In some aspects, the receive processor 258 and/or the controller 280 may determine, for a received signal (such as received from the network node 105 or another UE), one or more parameters relating to transmission of the uplink communication. The one or more parameters may include a reference signal received power (RSRP) parameter, a received signal strength indicator (RSSI) parameter, a reference signal received quality (RSRQ) parameter, a channel quality indicator (CQI) parameter, or a transmit power control (TPC) parameter, among other examples. The control information may include an indication of the RSRP parameter, the RSSI parameter, the RSRQ parameter, the CQI parameter, the TPC parameter, and/or another parameter. The control information may facilitate parameter selection and/or scheduling for the UE 115 by the network node 105.

The transmit processor 264 may generate reference symbols for a reference signal, such as an uplink DMRS, an uplink sounding reference signal (SRS), and/or another type of reference signal. The symbols from the transmit processor 264 may be precoded by a TX MIMO processor 266, if applicable, and further processed by the modems 254a through 254r (such as for DFT-s-OFDM or CP-OFDM, among other examples). The TX MIMO processor 266 may perform spatial processing (for example, precoding) on the data symbols, the control symbols, and/or the reference symbols, if applicable, and may provide a set of output symbol streams to the modems 254. For example, each output symbol stream may be provided to a respective modulator component (shown as MOD) of a modem 254. Each modem 254 may use the respective modulator component to process a respective output symbol stream (for example, for OFDM) to obtain an output sample stream. Each modem 254 may further use the respective modulator component to process (for example, convert to analog, amplify, filter, and/or upconvert) the output sample stream to obtain an uplink signal.

The modems 254a through 254r may transmit a set of uplink signals via the corresponding antennas 252a through 252r, respectively. An uplink signal may include a UCI communication, a MAC-CE communication, an RRC communication, or another type of uplink communication. Uplink signals may be transmitted on a PUSCH, a PUCCH, and/or another type of uplink channel. An uplink signal may carry one or more TBs of data. Sidelink data and control transmissions (that is, transmissions directly between two or more UEs 115) may generally use similar techniques as were described for uplink data and control transmission, and may use sidelink-specific channels such as a physical sidelink shared channel (PSSCH), a physical sidelink control channel (PSCCH), and/or a physical sidelink feedback channel (PSFCH).

At network node 105, the uplink signals from the UE 115 may be received by antennas 234a through 234t, processed by demodulator components of the modems 232a through 232t, detected by a MIMO detector 236 if applicable, and further processed by a receive processor 238 to obtain decoded data and/or control information sent by the UE 115. The receive processor 238 may provide the decoded data to a data sink 239 (which may be a data pipeline, a data queue, and/or another type of data sink) and provide the decoded control information to the controller 240.

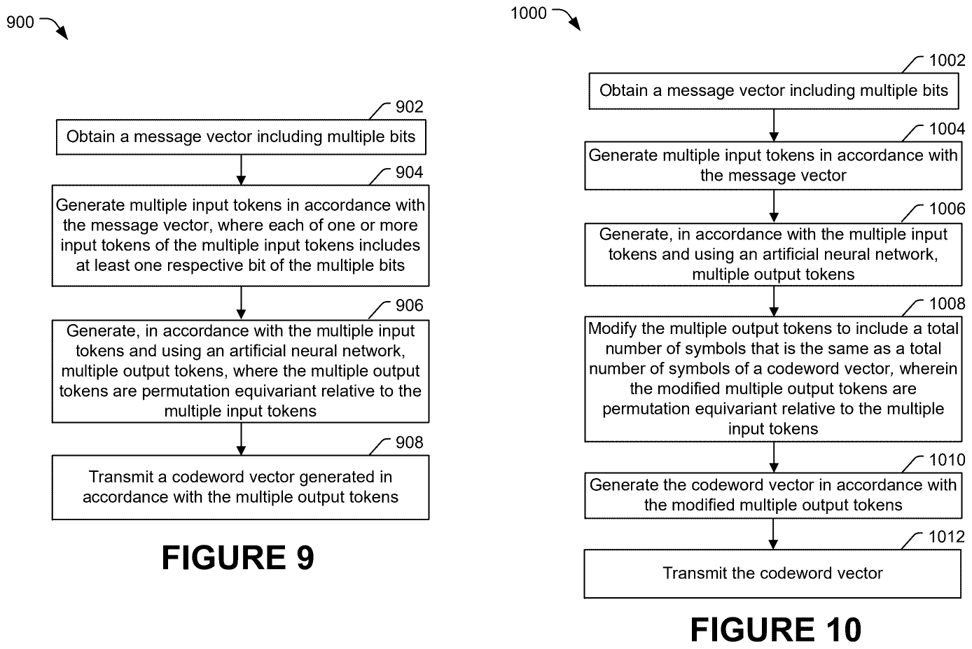

The controllers 240 and 280 may direct the operation at the network node 105 and the UE 115, respectively. The controller 240 (or other processors and modules at the network node 105) may perform or direct the execution of various processes for the techniques described herein. Similarly, the controller 280 (or other processors and modules at the UE 115) may perform or direct the execution of various processes for the techniques described herein, such as to perform or direct the execution illustrated in FIGS. 9-11, or other processes for the techniques described herein. For example, the controller 240 and/or the controller 280 may perform or control operations that support variable code-rate coding. Additionally, or alternatively, the UE 115 may include the communication manager 150 and the network node 105 may include the communication manager 152 that are configured to manage operations to support variable code-rate coding, as further described herein. Although referred to as “controllers”, the controllers 240 and 280 may include one or more processors and/or one or more controllers, and also or in the alternative be referred to as “processors” or “controller/processors”. In some aspects, a single processor may perform all of the operations described as being performed by the one or more processors or the one or more controllers. In some aspects, a first set of (one or more) processors of the one or more processors may perform a first operation described as being performed by the one or more processors, and a second set of (one or more) processors of the one or more processors may perform a second operation described as being performed by the one or more processors. The first set of processors and the second set of processors may be the same set of processors or may be different sets of processors.

The memories 242 and 282 may store data and program codes for the network node 105 and the UE 115, respectively. Reference to “one or more memories” should be understood to refer to any one or more memories of a corresponding device, such as the memory described in connection with FIG. 2. For example, an operation described as being performed by one or more memories can be performed by the same subset of the one or more memories or different subsets of the one or more memories.

The network node 105 may use a scheduler 246 to schedule one or more UEs 115 for downlink or uplink communications. In some aspects, the scheduler 246 may use DCI to dynamically schedule DL transmissions to the UE 115 and/or UL transmissions from the UE 115. In some examples, the scheduler 246 may allocate recurring time domain resources and/or frequency domain resources that the UE 115 may use to transmit and/or receive communications using an RRC configuration (for example, a semi-static configuration), for example, to perform semi-persistent scheduling (SPS) or to configure a configured grant (CG) for the UE 115.

In some examples, the network node 105 may use a communication unit 244 to communicate with a core network and/or with other network nodes. The communication unit 244 may support wired and/or wireless communication protocols and/or connections, such as Ethernet, optical fiber, common public radio interface (CPRI), and/or a wired or wireless backhaul, among other examples. The network node 105 may use the communication unit 244 to transmit and/or receive data associated with the UE 115 or to perform network control signaling, among other examples. The communication unit 244 may include a transceiver and/or an interface, such as a network interface.

One or more antennas of the antennas 252 or the antennas 234 may include, or may be included within, one or more antenna panels, one or more antenna groups, one or more sets of antenna elements, or one or more antenna arrays, among other examples. An antenna panel, an antenna group, a set of antenna elements, or an antenna array may include one or more antenna elements (within a single housing or multiple housings), a set of coplanar antenna elements, a set of non-coplanar antenna elements, or one or more antenna elements coupled with one or more transmission or reception components, such as one or more components of FIG. 2. As used herein, “antenna” can refer to one or more antennas, one or more antenna panels, one or more antenna groups, one or more sets of antenna elements, or one or more antenna arrays. “Antenna panel” can refer to a group of antennas (such as antenna elements) arranged in an array or panel, which may facilitate beamforming by manipulating parameters of the group of antennas. “Antenna module” may refer to circuitry including one or more antennas, which may also include one or more other components (such as filters, amplifiers, or processors) associated with integrating the antenna module into a wireless communication device.

In some examples, each of the antenna elements of an antenna 234 or an antenna 252 may include one or more sub-elements for radiating or receiving radio frequency signals. For example, a single antenna element may include a first sub-element cross-polarized with a second sub-element that can be used to independently transmit cross-polarized signals. The antenna elements may include patch antennas, dipole antennas, and/or other types of antennas arranged in a linear pattern, a two-dimensional pattern, or another pattern. A spacing between antenna elements may be such that signals with a desired wavelength transmitted separately by the antenna elements may interact or interfere constructively and destructively along various directions (such as to form a desired beam). For example, given an expected range of wavelengths or frequencies, the spacing may provide a quarter wavelength, a half wavelength, or another fraction of a wavelength of spacing between neighboring antenna elements to allow for the desired constructive and destructive interference patterns of signals transmitted by the separate antenna elements within that expected range.

The amplitudes and/or phases of signals transmitted via antenna elements and/or sub-elements may be modulated and shifted relative to each other (such as by manipulating phase shift, phase offset, and/or amplitude) to generate one or more beams, which is referred to as beamforming. The term “beam” may refer to a directional transmission of a wireless signal toward a receiving device or otherwise in a desired direction. “Beam” may also generally refer to a direction associated with such a directional signal transmission, a set of directional resources associated with the signal transmission (for example, an angle of arrival, a horizontal direction, and/or a vertical direction), and/or a set of parameters that indicate one or more aspects of a directional signal, a direction associated with the signal, and/or a set of directional resources associated with the signal. In some implementations, antenna elements may be individually selected or deselected for directional transmission of a signal (or signals) by controlling amplitudes of one or more corresponding amplifiers and/or phases of the signal(s) to form one or more beams. The shape of a beam (such as the amplitude, width, and/or presence of side lobes) and/or the direction of a beam (such as an angle of the beam relative to a surface of an antenna array) can be dynamically controlled by modifying the phase shifts, phase offsets, and/or amplitudes of the multiple signals relative to each other.

Different UEs 115 or network nodes 105 may include different numbers of antenna elements. For example, a UE 115 may include a single antenna element, two antenna elements, four antenna elements, eight antenna elements, or a different number of antenna elements. As another example, a network node 105 may include eight antenna elements, 24 antenna elements, 64 antenna elements, 128 antenna elements, or a different number of antenna elements. Generally, a larger number of antenna elements may provide increased control over parameters for beam generation relative to a smaller number of antenna elements, whereas a smaller number of antenna elements may be less complex to implement and may use less power than a larger number of antenna elements. Multiple antenna elements may support multiple-layer transmission, in which a first layer of a communication (which may include a first data stream) and a second layer of a communication (which may include a second data stream) are transmitted using the same time and frequency resources with spatial multiplexing.

FIG. 3 is a block diagram illustrating an example disaggregated base station architecture 300 in accordance with the present disclosure. One or more components of the example disaggregated base station architecture 300 may be, may include, or may be included in one or more network nodes (such as one or more network nodes 105). The disaggregated base station architecture 300 may include a CU 310 that can communicate directly with a core network 320 via a backhaul link, or that can communicate indirectly with the core network 320 via one or more disaggregated control units, such as a Non-RT RIC 350 associated with a Service Management and Orchestration (SMO) Framework 360 and/or a Near-RT RIC 370 (for example, via an E2 link). In some implementations, the core network 320 includes or corresponds to the core network 120 of FIG. 1. The CU 310 may communicate with one or more DUs 330 via respective midhaul links, such as via F1 interfaces. Each of the DUs 330 may communicate with one or more RUs 340 via respective fronthaul links. Each of the RUs 340 may communicate with one or more UEs 115 via respective RF access links. In some deployments, a UE 115 may be simultaneously served by multiple RUs 340.

Each of the components of the disaggregated base station architecture 300, including the CUs 310, the DUs 330, the RUs 340, the Near-RT RICs 370, the Non-RT RICs 350, and the SMO Framework 360, may include one or more interfaces or may be coupled with one or more interfaces for receiving or transmitting signals, such as data or information, via a wired or wireless transmission medium.

In some aspects, the CU 310 may be logically split into one or more CU user plane (CU-UP) units and one or more CU control plane (CU-CP) units. A CU-UP unit may communicate bidirectionally with a CU-CP unit via an interface, such as the E1 interface when implemented in an O-RAN configuration. The CU 310 may be deployed to communicate with one or more DUs 330, as necessary, for network control and signaling. Each DU 330 may correspond to a logical unit that includes one or more base station functions to control the operation of one or more RUs 340. For example, a DU 330 may host various layers, such as an RLC layer, a MAC layer, or one or more PHY layers, such as one or more high PHY layers or one or more low PHY layers. Each layer (which also may be referred to as a module) may be implemented with an interface for communicating signals with other layers (and modules) hosted by the DU 330, or for communicating signals with the control functions hosted by the CU 310. Each RU 340 may implement lower layer functionality. In some aspects, real-time and non-real-time aspects of control and user plane communication with the RU(s) 340 may be controlled by the corresponding DU 330.

The SMO Framework 360 may support RAN deployment and provisioning of non-virtualized and virtualized network elements. For non-virtualized network elements, the SMO Framework 360 may support the deployment of dedicated physical resources for RAN coverage requirements, which may be managed via an operations and maintenance interface, such as an O1 interface. For virtualized network elements, the SMO Framework 360 may interact with a cloud computing platform (such as an open cloud (O-Cloud) platform 390) to perform network element life cycle management (such as to instantiate virtualized network elements) via a cloud computing platform interface, such as an O2 interface. A virtualized network element may include, but is not limited to, a CU 310, a DU 330, an RU 340, a non-RT RIC 350, and/or a Near-RT RIC 370. In some aspects, the SMO Framework 360 may communicate with a hardware aspect of a 4G RAN, a 5G NR RAN, and/or a 6G RAN, such as an open eNB (O-eNB) 380, via an O1 interface. Additionally, or alternatively, the SMO Framework 360 may communicate directly with each of one or more RUs 340 via a respective O1 interface. In some deployments, this configuration can enable each DU 330 and the CU 310 to be implemented in a cloud-based RAN architecture, such as a vRAN architecture.

The Non-RT RIC 350 may include or may implement a logical function that enables non-real-time control and optimization of RAN elements and resources, AI/ML workflows including model training and updates, and/or policy-based guidance of applications and/or features in the Near-RT RIC 370. The Non-RT RIC 350 may be coupled to or may communicate with (such as via an A1 interface) the Near-RT RIC 370. The Near-RT RIC 370 may include or may implement a logical function that enables near-real-time control and optimization of RAN elements and resources via data collection and actions via an interface (such as via an E2 interface) connecting one or more CUs 310, one or more DUs 330, and/or an O-eNB with the Near-RT RIC 370.

In some aspects, to generate AI/ML models to be deployed in the Near-RT RIC 370, the Non-RT RIC 350 may receive parameters or external enrichment information from external servers. Such information may be utilized by the Near-RT RIC 370 and may be received at the SMO Framework 360 or the Non-RT RIC 350 from non-network data sources or from network functions. In some examples, the Non-RT RIC 350 or the Near-RT RIC 370 may tune RAN behavior or performance. For example, the Non-RT RIC 350 may monitor long-term trends and patterns for performance and may employ AI/ML models to perform corrective actions via the SMO Framework 360 (such as reconfiguration via an O1 interface) or via creation of RAN management policies (such as A1 interface policies).

The UEs 115, the CU 310, the DUs 330, the RUs 340, or any other component(s) of FIG. 3 may implement one or more techniques or perform one or more operations associated with variable code-rate coding, as described further herein. For example, the UEs 115 may include the communication manager 150 and the RUs 340 may include the communication manager 152, which may manage operations to support variable code-rate coding. Although shown as being included in a single UE 115 in FIG. 3, any of the UEs 115 may include the communication manager 150, and although shown as being included in a single RU 340 in FIG. 3, any of the RUs 340, the DUs 330, the CU 310, the Non-RT RIC 350, the SMO Framework 360, the Near-RT RIC 370, or a combination thereof, may include the communication manager 152. The communication manager 150 may direct operations of, for example, the process of any of FIGS. 9-11, or other processes as described herein (alone or in conjunction with one or more other processors). Similarly, the communication manager 152 may direct operations of one or more processes as described herein (alone or in conjunction with one or more other processors).

In some examples, the communication manager 150 or the communication manager 152 may include, or have access to, a non-transitory computer-readable medium storing a set of instructions (for example, code or program code) for wireless communication. The memory may include one or more memories, such as a single memory or multiple different memories (of the same type or of different types). For example, the set of instructions, when executed (for example, directly, or after compiling, converting, or interpreting) by the communication manager 150 or one or more processors of the UE 115 may cause the one or more processors or the communication manager 150 to perform the process of any of FIGS. 9-11, or other processes as described herein. As another example, the set of instructions, when executed (for example, directly, or after compiling, converting, or interpreting) by the communication manager 152, one or more processors of the network node 105, the CU 310, the DU 330, the RU 340, the Non-RT RIC 350, the SMO Framework 360, or the Near-RT RIC 370, may cause the one or more processors or the communication manager 152 to perform one or more processes as described herein. In some examples, executing instructions may include running the instructions, converting the instructions, compiling the instructions, and/or interpreting the instructions, among other examples.

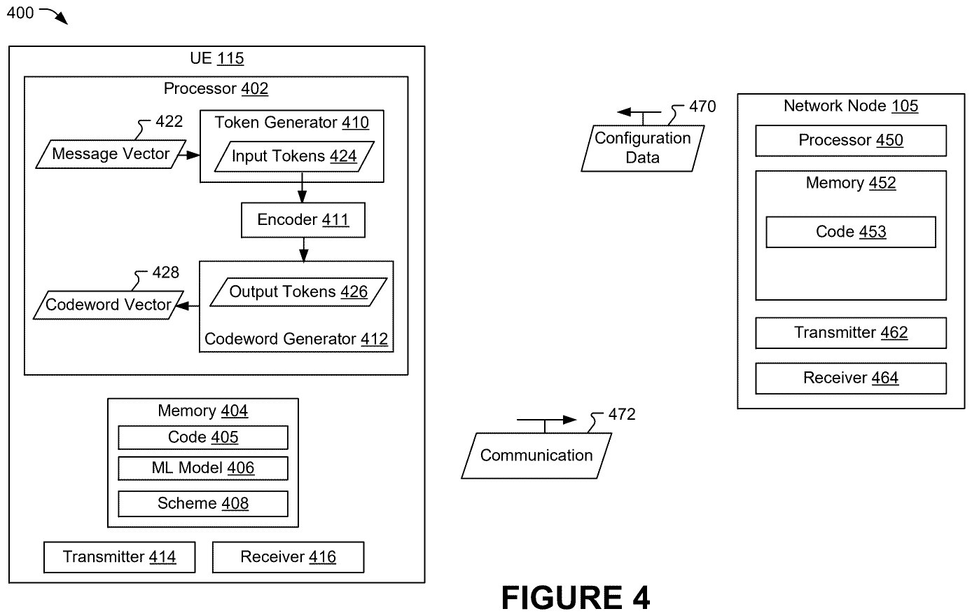

FIG. 4 is a block diagram illustrating an example wireless communication system 400 that supports variable code-rate coding in accordance with the present disclosure. In some examples, the wireless communication system 400 may implement aspects of the wireless communication network 100. The wireless communication system 400 includes the UE 115 and the network node 105. Although one UE 115 and one network node 105 are illustrated, in some other implementations, the wireless communication system 400 may generally include multiple UEs 115, multiple network nodes 105, or both. Additionally, or alternatively, the wireless communication system 400 may include another device, such as a server.

The UE 115 can include a variety of components (such as structural, hardware components) used for carrying out one or more functions described herein. For example, these components can include one or more processors 402 (hereinafter referred to collectively as “the processor 402”), one or more memory devices 404 (hereinafter referred to collectively as “the memory 404”), one or more transmitters 414 (hereinafter referred to collectively as “the transmitter 414”), and one or more receivers 416 (hereinafter referred to collectively as “the receiver 416”). Although referred to as a processor 402, the UE 115 may include one or more chips, system-on-chips (SoCs), chipsets, packages, or devices that individually or collectively constitute or include a processing system. The processing system includes processor (or “processing”) circuitry in the form of one or multiple processors (such as the processor 402), microprocessors, processing units (such as central processing units (CPUs), graphics processing units (GPUs), neural processing units (NPUs) and/or digital signal processors (DSPs)), processing blocks, application-specific integrated circuits (ASIC), programmable logic devices (PLDs) (such as field programmable gate arrays (FPGAs)), or other discrete gate or transistor logic or circuitry (all of which may be generally referred to herein individually as “processors” or collectively as “the processor 402” or “the processor circuitry”).

One or more of the processors 402 may be individually or collectively configurable or configured to perform various functions or operations described herein. A group of processors, such as the processors 402, collectively configurable or configured to perform a set of functions may include a first processor configurable or configured to perform a first function of the set of functions and a second processor configurable or configured to perform a second function of the set of functions, or may include the group of processors all being configured or configurable to perform the set of functions. The processor 402 may be configured to execute code 405, such as one or more instructions, stored in the memory 404 to perform the operations described herein. In some implementations, the processor 402 includes or corresponds to the receive processor 258, the transmit processor 264, the controller 280, or a combination thereof, and the memory 404 includes or corresponds to the memory 282, described with reference to FIG. 2. In some implementations, the processor 402, the memory 404, the code 405, another component of the UE 115, or a combination thereof, may include or correspond to the communication manager 150 of FIGS. 1-3 and/or may perform the operations associated with the communication manager 150 to support variable code-rate coding. In some implementations, a “processing system” includes one or more processors (the processor 402) and one or more memories (the memory 404) that store the code 405 and are coupled with one or more processors. In such embodiments, such a processing system is configured to cause the UE 115 to perform the operations described herein.

The processor 402 may include or implement a token generator 410, an encoder 411, and a codeword generator 412. Although the token generator 410, the encoder 411, and the codeword generator 412 are described as being separate components, in other implementations, two or more of the token generator 410, the encoder 411, or the codeword generator 412 may be combined. For example, in some implementations, the encoder 411 may include the codeword generator 412 or a portion of the codeword generator 412.

The token generator 410 is configured to obtain a message vector 422, such as by receiving the message vector 422 from an application executed by the processor 402 or by generating the message vector 422, as non-limiting examples. In some implementations, the message vector 422 is a one dimensional vector. The message vector 422 may include a number of information bits k, such as one or more information bits. It is noted that the number of information bits k may vary between different message vectors obtained by the token generator 410, such that a first message vector and a second message vector include different respective numbers of information bits.

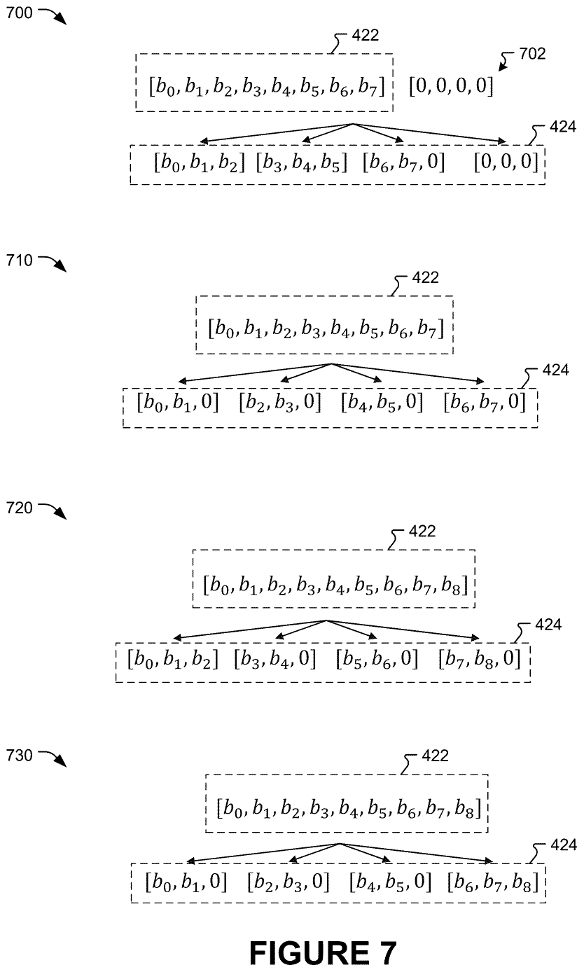

The token generator 410 is also configured to generate multiple input tokens 424 (also referred to collectively hereinafter as “the input tokens 424”). A total number of bits included in the input tokens 424 may be associated with a number of input bits that the encoder 411, or an ML model 406 used by the encoder 411, is configured or trained to receive. In some implementations, the token generator 410 is configured to generate the input tokens 424 in accordance with the message vector 422. The input tokens 424 may include a sequence of non-overlapping vectors. In some implementations, the token generator 410 may generate the multiple input tokens 424 according to a scheme 408, as described further herein at least with reference to FIG. 7. In some implementations, when the total number of bits included in the input tokens 424 is greater than a total number of bits included in the message vector 422, the token generator 410 generates the input tokens 424 such that each of one or more input tokens of the input tokens 424 includes at least one respective bit of the multiple bits of the message vector 422 and, optionally, one or more padding bits (one or more zeros).

The encoder 411 is configured to perform a channel coding operation on received input tokens to generate encoded output tokens. To perform the channel coding operation, the encoder 411 may receive the input tokens 424 and generate multiple output tokens 426 (also referred to collectively hereinafter as “the output tokens 426”). In some implementations, the encoder 411 may be configured to receive a maximum number of information bits kₘₐₓ, one or more input tokens that each have a size token_size, a number of input tokens A, or a combination thereof. In a particular example, the maximum number of information bits kₘₐₓ is eleven. Additionally, or alternatively, a relationship between the number of input tokens A, the maximum number of information bits kₘₐₓ, and the size token_size of one or more input tokens may be defined as A=kₘₐₓ/token_size.

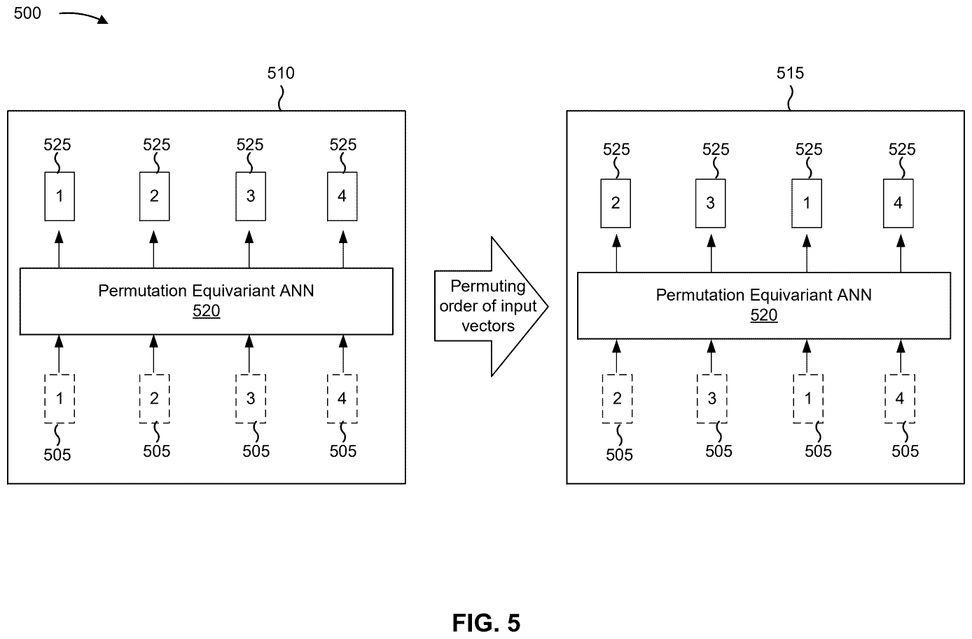

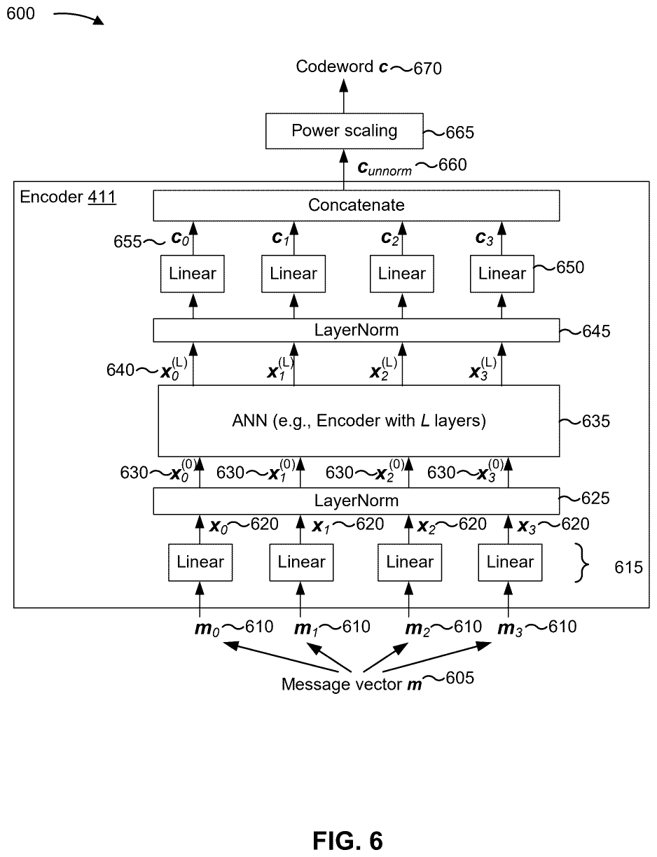

In some implementations, the encoder 411 may generate the output tokens 426 in accordance with the multiple input tokens 424 and using the ML model 406, such as an artificial neural network. The output tokens 426 may be permutation equivariant relative to the multiple input tokens 424, as described further herein at least with reference to FIG. 5. An example of the encoder 411 configured to use the ML model 406 is described further herein at least with reference to FIG. 6. A total number of symbols collectively included in the multiple output tokens 426 may be equal to a number of output symbols that the encoder 411, such as the ML model 406, is configured or trained to output. For example, the encoder 411 may be configured to output a maximum number of coded symbols nₘₐₓ, and the total number of symbols collectively included in the multiple output tokens 426 is equal to nₘₐₓ.

The codeword generator 412 is configured to obtain the output tokens 426, such as by receiving the output tokens 426 from the encoder 411, and the codeword generator 412 is configured to generate a codeword vector 428 in accordance with the output tokens 426. The codeword vector 428 is a one-dimensional vector and may include a number of coded symbols n, such as one or more coded symbols. It is noted that the number of coded symbols n may vary between different codeword vectors output by the codeword generator 412, such that a first codeword vector includes more or fewer symbols than a second codeword vector.

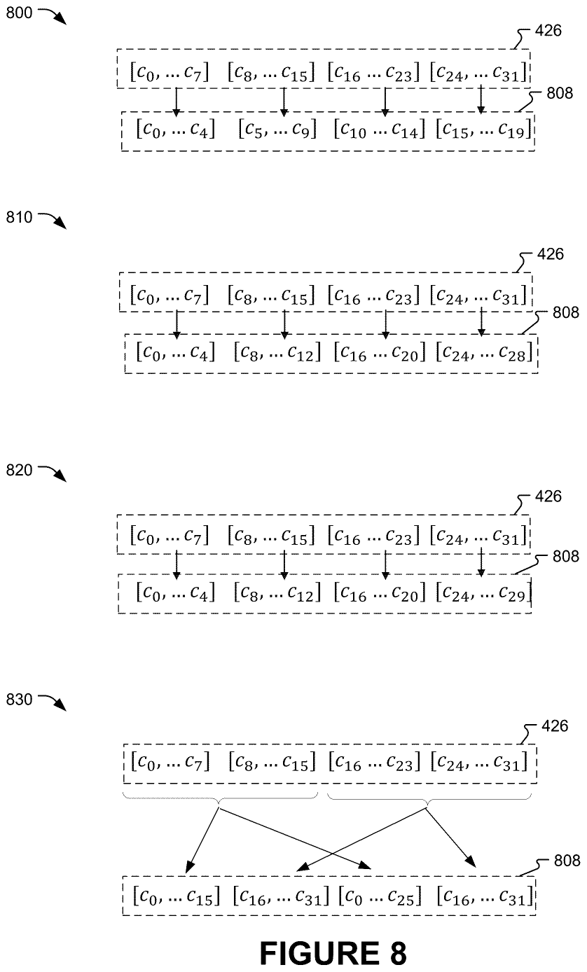

In some implementations, the codeword generator 412 is configured to concatenate the output tokens 426 to generate the codeword vector 428. Additionally, or alternatively, the codeword generator 412 may generate modified output tokens (not shown) according to a scheme 408, as described further herein. For example, the codeword generator 412 may modify, according to the scheme 408, the output tokens 426 to generate modified output tokens, as described further herein at least with reference to FIG. 8. The modified multiple output tokens may be permutation equivariant relative to the input tokens 424. The codeword generator 412 may combine (such as concatenate) the modified output tokens to generate the codeword vector 428.

The memory 404 may be configured to store the code 405, an ML model 406, and one or more schemes 408 (hereinafter referred to collectively as “the scheme 408”). The ML model 406 may include an artificial neural network that is a permutation-equivariant artificial neural network. The ML model 406, such as the artificial neural network, may include at least one of a transformer, a graph neural network, a self-attention layer, a layer normalization layer, a position-wise multi-layer perceptron, an average-pooling layer, or a max-pooling layer. Examples of the ML model 406, such as the artificial neural network, are described further herein at least with reference to FIG. 6. In some implementations, the UE 115 may receive the ML model 406, of parameters thereof, from a model sever for implementing the ML model 406 at the UE 115.

The scheme 408 indicates one or more techniques to be used by the token generator 410 to generate the input tokens 424 from the message vector 422, one or more techniques to be used by the codeword generator 412 to generate the codeword vector 428 from the output tokens 426, or a combination thereof. For example, the scheme 408 may support channel coding for varying numbers of information bits k, for varying numbers of coded symbols n, or both. Examples of techniques to generate the input tokens 424 from the message vector 422 are described further herein at least with reference to FIG. 7. Examples of techniques to generate the codeword vector 428 from the output tokens 426 are described further herein at least with reference to FIG. 8.

In some implementations, the scheme 408 may include a first input token scheme that indicates, when k is less than kₘₐₓ, to append the information bits of the message vector 422 with one or more zeros, where a number of zeros to be appended is determined as kₘₐₓ−k. The combination of the information bits of the message vector 422 and the appended one or more zeros may then be distributed among the input tokens 424 by the token generator 410. For example, a first group of bits selected from the combination of the information bits and the one or more zeros may be distributed to a first input token of the input tokens 424, and a second group of bits selected from the combination of the information bits and the one or more zeros may be distributed to a second input token of the input tokens 424. In some such implementations, at least a final input token of the input tokens 424 includes all zeros.

In some implementations, the scheme 408 may include a second input token scheme that indicates, when k is less than kₘₐₓ, to distribute the information bits of the message vector 422 among the input tokens 424. For example, the second input token scheme may indicate to identify the number of input tokens A and determine a number of information bits to be assigned to each input token as k/A. A remaining number of bits for each input token may be set to zero or otherwise include one or more zeroes that are appended to the respective input token. Accordingly, each input token of the input tokens 424 may include the same number of respective bits from the message vector 422 and the same number of zeros as each of the other input tokens of the input tokens 424.

In some implementations, when the number of information bits k is not a multiple of the number of input tokens A and when k is less than kₘₐₓ, the scheme 408 may indicate to determine a first number of respective bits of the message vector 422 to be assigned to each of one or more first input tokens of the input tokens 424, and a second number of respective bits of the message vector 422 to be assigned to one or more second input tokens of the input tokens 424. The first number of respective bits may be a different value than the second number of respective bits. It is noted that one or more zeros may be added, as needed, to each of the one or more first input tokens and/or each of the one or more second input tokens, to fill a respective input token such that all input tokens have the same size. For example, the first number of respective bits may be determined in accordance with a ceiling operation, such as ceil (k/A), and the second number of respective bits may be determined in accordance with a floor operation, such as floor (k/A). Additionally, it is noted that the number of input tokens A is equal to the sum of the one or more first input tokens and the one or more second input tokens. The scheme 408 may also indicate which input tokens of the input tokens 424 are to be the one or more first input tokens, and which input tokens of the input tokens 424 are to be the one or more second input tokens. For example, the one or more first input tokens may include one or more initial token of the input tokens 424, as described below with reference to a third input token scheme, or one or more last input tokens of the input tokens 424, as described below with reference to a fourth input token scheme. One or more zeros may be added to each input token so that each token has the appropriate token_size, such as a number of bits of each input token.

In some implementations, the scheme 408, such as the third input token scheme, may indicate that one or more initial tokens of the input tokens 424 includes the one or more first input tokens (each having ceil (k/A) respective bits), and the other tokens of the input tokens 424 include the one or more second input tokens (each having floor (k/A) respective bits). In some implementations, the scheme 408, such as the fourth input token scheme, may indicate that one or more last tokens of the input tokens 424 includes the one or more first input tokens (each having ceil (k/A) respective bits), and the other tokens of the input tokens 424 include the one or more second input tokens (each having floor (k/A) respective bits).

It is noted that when k is equal to kₘₐₓ, the scheme 408 may indicate to distribute the information bits of the message vector 422 equally among the input tokens 424. It is further noted that when k is greater than kₘₐₓ, the scheme 408 may indicate to divide the message vector 422 into one or more vectors each having kₘₐₓ information bits and, if applicable, one vector having less than kₘₐₓ information bits. The one vector having less than kₘₐₓ information bits may be provided to the token generator 410 and the token generator 410 may generate corresponding input tokens 424 using the scheme 408, such as one of the input token schemes described herein.

In some implementations, the scheme 408 may indicate which input token scheme is to be used. For example, the first input token scheme may be used when k is less than kₘₐₓ and when kₘₐₓ−k is less than or equal to the total number of bits (token_size) of a respective input token of the multiple input token. As another example, the first input token scheme may be used when k is less than kₘₐₓ and when kₘₐₓ−k is less than twice the total number of bits (token_size) of a respective input token of the multiple input token. Additionally, or alternatively, the second input token scheme may be used when k is less than kₘₐₓ and when the number of information bits k is a multiple of the number of input tokens A. In some implementations, the third input token scheme is used when k is less than kₘₐₓ and when the number of information bits k is not a multiple of the number of input tokens A. Additionally, or alternatively, the scheme 408 may also indicate that when k is less than kₘₐₓ and when k is less than or equal a threshold, such as three, or when k is less than or equal to the number of input tokens A−1, to use a predefined table, such as a table defined by a wireless communication standard. Accordingly, the scheme 408 may indicate one or more conditions to enable selection of a particular input token scheme of multiple input schemes in accordance with the number of information bits k.

In some implementations, the scheme 408 includes a first output token scheme that indicates, when n is less than nₘₐₓ, to drop nₘₐₓ−n coded symbols from the output tokens 426 to generate the codeword vector 428. Stated differently, the first output token scheme may indicate to remove, for at least one output token of the multiple output tokens 426, at least one symbol from the at least one output token. The at least one output token may include a final output token of the output tokens 426, and the at least one symbol may include at least the last coded symbol of the respective output token. The coded symbols of the output tokens 426 that have not been removed or dropped may be combined, such as concatenated, by the codeword generator 412 to form the codeword vector 428.

In some implementations, the scheme 408 includes a second output token scheme that indicates, when n is less than nₘₐₓ, to retain one or more coded symbols from each output token of the output tokens 426 and to drop the remaining unretained coded symbols. For example, the second output token scheme may indicate to identify the number of input tokens A (which may also be the number of output tokens) and determine a number of coded symbols to be retained for each output token as n/A. The remaining unretained coded symbols of each output token may be dropped during the generation process for the codeword vector 428. In some implementations, the same number of coded symbols may be dropped from each output token of the output tokens 426. The coded symbols of the output tokens 426 that have not been removed or dropped may be combined, such as concatenated, by the codeword generator 412 to form the codeword vector 428.

In some implementations, the scheme 408 includes a third output token scheme that indicates, when n is less than nₘₐₓ and when n is not a multiple of the total number of the output tokens 426, to determine a first number of coded symbols to be removed from each of one or more first output tokens of the output tokens 426, and a second number of coded symbols to be removed from each of one or more second output tokens of the output tokens 426. The second number of symbols may be different from the first number of symbols. The third output token scheme may also indicate which output tokens of the output tokens 426 are included in the one or more first output tokens and which output tokens of the output tokens 426 are included in the one or more second output tokens. For example, the one or more first output tokens may include one or more initial token of the output tokens 426, or one or more last input tokens of the output tokens 426. The coded symbols of the output tokens 426 that have not been removed or dropped may be combined, such as concatenated, by the codeword generator 412 to form the codeword vector 428.

It is noted that when n is equal to nₘₐₓ, the scheme 408 may indicate to combine (concatenate) the output tokens 426 to form the codeword vector 428. It is further noted that when n is greater than nₘₐₓ, the scheme 408 may indicate to perform a repetition operation a repetition operation using at least a portion of at least one output token of the output tokens 426 to modify the output tokens 426 to include the total number of symbols (nₘₐₓ) of the codeword vector 428. For example, the portion of the at least one output token may include at least an initial coded symbol of initial output token of the output tokens 426, and the portion may be added after a last coded symbol of the last output token of the output tokens 426 to increase the number of coded symbols to equal the total number of symbols (nₘₐₓ) of the codeword vector 428.

The transmitter 414 is configured to transmit reference signals, control information and data to one or more other devices, and the receiver 416 is configured to receive reference signals, synchronization signals, control information and data from one or more other devices. For example, the transmitter 414 may transmit signaling, control information and data to, and the receiver 416 may receive signaling, control information and data from, the network node 105. In some implementations, the transmitter 414 and the receiver 416 may be integrated in one or more transceivers. Additionally, or alternatively, the transmitter 414 or the receiver 416 may include or correspond to one or more components of the UE 115 described with reference to FIG. 2.

The network node 105 can include a variety of components (such as structural, hardware components) used for carrying out one or more functions described herein. For example, these components can include one or more processors 450 (hereinafter referred to collectively as “the processor 450”), one or more memory devices 452 (hereinafter referred to collectively as “the memory 452”), one or more transmitters 462 (hereinafter referred to collectively as “the transmitter 462”), and one or more receivers 464 (hereinafter referred to collectively as “the receiver 464”). Although referred to as a processor 450, the network node 105 may include one or more chips, SoCs, chipsets, packages, or devices that individually or collectively constitute or include a processing system. The processing system includes processor (or “processing”) circuitry in the form of one or multiple processors (such as the processor 450), microprocessors, processing units (such as CPUs, GPUs, NPUs and/or DSPs), processing blocks, ASICs, PLDs (such as FPGAs), or other discrete gate or transistor logic or circuitry (all of which may be generally referred to herein individually as “processors” or collectively as “the processor 450” or “the processor circuitry”).

One or more of the processors 450 may be individually or collectively configurable or configured to perform various functions or operations described herein. A group of processors, such as the processors 450, collectively configurable or configured to perform a set of functions may include a first processor configurable or configured to perform a first function of the set of functions and a second processor configurable or configured to perform a second function of the set of functions, or may include the group of processors all being configured or configurable to perform the set of functions. The processor 450 may be configured to execute code 453, such as one or more instructions, stored in the memory 452 to perform the operations described herein. In some implementations, the processor 450 includes or corresponds to the receive processor 238, the transmit processor 220, the controller 240, or a combination thereof, and the memory 452 includes or corresponds to the memory 242, described with reference to FIG. 2. In some implementations, the processor 450, the memory 452, the code 453, another component of the network node 105, or a combination thereof, may include or correspond to the communication manager 152 of FIGS. 1-3 and/or may perform the operations associated with the communication manager 152 to support variable code-rate coding. In some implementations, a “processing system” includes one or more processors (the processor 450) and one or more memories (the memory 452) that store the code 453 and are coupled with one or more processors. In such embodiments, such a processing system is configured to cause the network node 105 to perform the operations described herein. The memory 452 may be configured to store the code 453.

The transmitter 462 is configured to transmit reference signals, synchronization signals, control information, and data to one or more other devices, and the receiver 464 is configured to receive reference signals, control information and data from one or more other devices. For example, the transmitter 462 may transmit signaling, control information and data to, and the receiver 464 may receive signaling, control information and data from, the UE 115. In some implementations, the transmitter 462 and the receiver 464 may be integrated in one or more transceivers. Additionally, or alternatively, the transmitter 462 or the receiver 464 may include or correspond to one or more components of network node 105 described with reference to FIG. 2.

In some implementations, the wireless communication system 400 is configured to implement a 5G NR network or a 6G network. For example, the wireless communication system 400 may include multiple 5G-capable UEs 115 (or 6G-capable UEs 115) and multiple 5G-capable network nodes 105 (or 6G-capable network nodes 105), such as UEs and network nodes configured to operate in accordance with a 5G NR network protocol, or a 6G network protocol, such as that defined by the 3GPP.

During operation of the wireless communication system 400, the network node 105 may transmit configuration data 470 to the UE 115. The configuration data 470 may include or correspond to RRC signaling, medium access control-control element (MAC-CE) signaling, downlink control information (DCI), system information, or the like. In some implementations, the configuration data 470 may indicate a set of parameters for an AI/ML model, such as the ML model 406. For example, the set of parameters may include parameters for a common input linear layer, an ANN, a common output linear layer, another element of the ML model 406, or a combination thereof. Additionally, or alternatively, the set of parameters may include a set of weights, a set of biases, a number of layers, other neural network or ML model parameters, or a combination thereof. An example of the ML model 406 is described herein with reference to FIG. 5. In some implementations, the configuration data 470 may include an indicator that indicates the ML model 406. Additionally, or alternatively, the ML model 406 or the configuration data 470 may indicate a total number of input tokens of the input tokens 424, a total number of symbols of the codeword vector 428, the scheme 408, or a combination thereof.

The UE 115 receives the configuration data 470 and may perform one or more operations in accordance with the set of parameters indicated by the configuration data 470. For example, the UE 115 may perform channel coding, such as permutation-equivariant neural network channel coding. In some examples, the UE 115 performs the channel coding using the token generator 410, the encoder 411, the codeword generator 412, or a combination thereof. In some implementations, the UE 115 may select the scheme 408 to be used as part of, or in association, with the channel coding.

The UE 115 obtains obtain the message vector 422 including multiple bits. In some examples, the message vector 422 includes a bit vector, such as the bit vector b as described herein at least with reference to FIG. 6. The UE 115 may provide the message vector 422 as input to the token generator 410.

The UE 115, such as the token generator 410, may generate the input tokens 424 in accordance with the message vector 422. In some examples, the input tokens 424 may include or correspond to a set of message sub-vectors, as described herein at least with reference to message sub-vectors 610 of FIG. 6. In some implementations, the input tokens 424 are generated in accordance with the scheme 408, such as an input token scheme. Additionally, or alternatively, the total number of bits included in the input tokens 424 may be greater than a total number of bits included in the message vector 422. In some implementations, a total number of bits included in the input tokens 424 is associated with a maximum number of input bits that can be received at any given time as input to the encoder 421, such as a maximum number of bits that the ML model 406 is configured or trained to receive and processes at a given time.

Each input token of one or more input tokens of the input tokens 424 includes at least one respective bit of the multiple bits of the message vector 422. In some such implementation, at least one input token of the input tokens includes all zeros. Alternatively, in some implementations, each input token of the input tokens 424 includes at least one respective bit of the multiple bits.

The UE 115, such as the encoder 411, may generate, in accordance with the input tokens 424 and using an artificial neural network, the output tokens 426. The artificial neural network may include or correspond to the ML model 406. The output tokens 426 may be permutation equivariant relative to the input tokens 424. In some implementations, a total number of symbols included in the output tokens 426 is equal to a maximum number of output symbols that encoder 411 (or the artificial neural network) is configured or trained to output.

In some implementations, to generate the output tokens 426, the encoder 411 may generate, in accordance with one or more first linear projection operations, multiple input embedding vectors corresponding to the input tokens 424. Additionally, the encoder 411 may generate, by a transformer encoder using the artificial neural network, multiple output embedding vectors corresponding to the multiple input embedding vectors. The encoder 411 may also generate, using the multiple output embedding vectors and in accordance with one or more second linear projection operations, the output tokens 426.

The UE 115, such as the codeword generator 412, may generate, in accordance with the output tokens 426, the codeword vector 428. For example, to generate the codeword vector 428, the codeword generator 412 may combine, such as concatenate, the output tokens 426. As another example, to generate the codeword vector 428, the codeword generator 412 may modify the output tokens 426 and combine, such as concatenate, the modified output tokens. To illustrate, the codeword generator 412 may modify the output tokens 426 to include a total number of symbols that is the same as a total number of symbols of the codeword vector 428, which may be a total/maximum number of symbols that the codeword generator 412 is configured to output and/or that the ML model 406 is configured or trained to generate. The modified output tokens 426 may be permutation equivariant relative to the input tokens 424. In some implementations, the modified output tokens 426, the codeword vector 428, or both, are generated in accordance with the scheme 408, such as an output token scheme.

In some implementations, the UE 115 may identify the codeword vector 428 using a table, such as the table as described with reference to FIG. 6. In some such implementations, multiple tables may be predefined and stored at the UE 115, the network node 105, or both, and such tables may be preconfigured at the various devices and/or defined by a wireless communication specification. An example of one such table is provided in connection with FIG. 6. A table, of the multiple tables, may correspond to a number of message sub-vectors into which a message vector is divided. Additionally, or alternatively, a table may correspond to a number of bits to pad and/or which message sub-vector contains the padding bits. In some implementations, the UE 115 may identify a table that corresponds to a number of message sub-vectors into which a message vector is divided, a number of bits to pad, and a message sub-vector to contain the padding bits, and the UE 115 may identify the codeword vector according to the table. In some aspects, the UE 115 may be configured with information indicating the number of message sub-vectors, the number of bits to pad, and/or which message sub-vector to pad.

The UE 115 transmits a communication 472, such as an encoded communication that is encoded in accordance with the codeword vector 428. The communication 472 may be transmitted to the network node 105 or to a wireless communication device (not shown in FIG. 4). It is noted that channel codes generated by AI/ML may take values from the set of real numbers (as opposed to binary values), meaning that a codeword (such as the codeword vector 428) can be transmitted without being subject to modulation (such as quadrature amplitude modulation). Accordingly, the UE 115 may perform joint coding and modulation. Additionally, or alternatively, the communication 472 may include or indicate the input tokens 424, the output tokens 426, the codeword vector 428, the scheme 408, or a combination thereof.

The network node 105 may receive the communication 472. In some implementations the network node 105 may decode the communication 472. For example, the network node 105 may be configured to decode the communication without (independent of) an ML model because of the equivariance property associated with the codeword vector 428.

It is noted that although operations are described with reference to the UE 115, in some implementations, the network node 105 may perform one or more operations as described with reference to the UE 115 to enable the network node 105 to perform variable code-rate coding. In such implementations, it also noted that the UE 115 may be configured to perform one or more operations as described with reference to the network node 105 to enable the UE 115 to perform a decoding operation.

As described with reference to FIG. 4, the wireless communication system 400 supports variable code-rate coding by one or more wireless communication devices. In some aspects, by generating the output tokens 426 or the modified output tokens that are permutation equivariant relative to the input tokens 424, a structure is enforced in a respective codebook that can be exploited for simpler decoding of a codeword, such as the codeword vector 428, by a receiving device. For example, a table may define a codeword sub-vector, associated with the output tokens 426 or the modified output tokens, that corresponds to a message sub-vector associated with the input tokens 424 in a fashion that exploits the permutation equivariance to reduce a size of the table relative to a table that explicitly defines all possible mappings of message vectors and codeword vectors. Thus, complexity of decoding of AI/ML-based channel codes at the network node 105, or other wireless communication devices, is reduced as compared to using other AI/ML-based channel codes.

FIG. 5 is a diagram illustrating an example 500 of permutation equivariance in accordance with the present disclosure. Permutation equivariance is a property used in aspects described herein to provide structure in a codebook generated by an ANN. As used herein, “permutation equivariance” may refer to a property in which permutating inputs to a model results in a same permutation of outputs from the model, such as described below in connection with an ANN 520. The ANN 520 may include or correspond to the ML model 406 of FIG. 4.

In the example 500, a set of inputs 505 are shown with dashed outlines and numbered 1, 2, 3, and 4. The set of inputs 505 may include, for example, vectors, sub-vectors, values, patches, tokens, or the like. For example, the set of inputs 505 may include or correspond to the message vector 422 or the input tokens 424. A first permutation of the set of inputs 505 is shown by reference number 510 and a second permutation of the set of inputs 505 is shown by reference number 515. As shown, the set of inputs 505 is input to the ANN 520 (which may also include or correspond to, for example, an ANN 635, described below with reference to FIG. 6). The ANN 520 outputs a set of outputs 525. The set of outputs 525 may include, for example, vectors, sub-vectors, values, patches, tokens, or the like. For example, the set of outputs 525 may include or correspond to the output tokens 426 or the codeword vector 428. As shown in FIG. 5, the set of outputs 525 has a same permutation as the set of inputs 505 for the first permutation shown by reference number 510. Furthermore, the set of outputs 525 has a same permutation as the set of inputs 505 for the second permutation shown by reference number 515. Thus, the set of outputs 525 are said to be permutation-equivariant with regard to the set of inputs 505.

Permutation equivariance is a property in which an input of the ANN 520 (such as the set of inputs 505), and an output of the ANN 520 (such as the set of outputs 525), behave in the same way under a permutation operation on the set of inputs. Permutation equivariance can be contrasted against permutation invariance, which is a property in which an output of the ANN 520 would be invariant when the input is permuted. A set of neural network operations denoted by f_{θ} is permutation-equivariant if, for any permutation matrix Π, the following condition is satisfied:

$$\prod {f}_{θ} ( M ) = {f}_{θ} ( \prod M ) ,$$

where M represents a matrix of input vectors. On the other hand, f_{θ} is permutation invariant if, for any Π, f_{θ}(ΠM)=f_{θ}(M). Thus, the set of outputs 525 (such as a set of codeword sub-vectors, described below) is permutation-equivariant relative to the set of inputs 505 (such as a set of message sub-vectors, described below) for all permutations of the set of inputs 505.

FIG. 6 is a diagram illustrating an example 600 of channel coding using an AI/ML model in accordance with the present disclosure. In some aspects, the operations of the example 600 may be performed by a device, such as a transmitter device (which may include a UE 115, a network node 105, a CU 310, a DU 330, or an RU 340), a model server, or the like.

As shown, the device may obtain a message vector 605, denoted m. The message vector may include or correspond to the message vector 422 of FIG. 4. In some aspects, the message vector 605 m may include a number k of elements m₀ . . . mₖ₋₁. It is noted that references to sub-vectors of the message vector 605 m are denoted by bold and italics (mₙ) with a subscript denoting the sub-vector index, whereas references to elements of the message vector 605 m are denoted by italics without bold and with a subscript denoting the message element index (mᵢ). Similar notation is used throughout this description.

In some aspects, the device may generate the message vector 605 m using a 1×k bit vector b that includes k elements. For example, the bit vector b may include k binary values (b∈{0, 1}^{k}). In some aspects, the device may generate the message vector 605 m by converting bit values of the bit vector b into values of the message vector 605 m using a mapping mᵢ=(−1)^{b}^{ᵢ}, where bᵢ is the i-th element of b, and mᵢ is the i-th element of m. Thus, m∈{−1, 1}^{k}. This may be considered modifying values of the message vector 605 m. In other implementations, the bit vector b may be mapped to the message vector 605 m using another technique. Generating the message vector 605 m in this fashion may improve performance of an ANN that receives and processes the message vector 605 m relative to inputting the bit vector (or bit values) directly into the ANN.

As shown in FIG. 6, the device may generate a set of message sub-vectors 610, denoted {mᵢ}, using the message vector 605 m. For example, the device may split the message vector 605 m into a set of non-overlapping message sub-vectors 610, which may be referred to as patching. The message sub-vectors 610 may include or correspond to the input tokens 424 of FIG. 4. Each message sub-vector 610 may be referred to as a token. For a 1×k message vector including k=11 elements, the message vector 605 may be split into 4 message sub-vectors 610: m=[m₀, m₁, m₂, m₃], where m₀=[m₀, m₁, m₂], m₁=[m₃, m₄, m₅], m₂=[m₆, m₇, m₈], and m₃=[m₉, m₁₀, 1]. In this example, m₃ includes a padding value (the value of 1 in this example). In some aspects, the padding value may be a possible value of mᵢ, such as 1 or −1. In some aspects, the device may insert the padding value into the bit vector b (before converting the bit vector b into the message vector 605), in which case the padding value may be a possible value of bᵢ, such as 0 or 1. For example, the device may insert the padding value into a message sub-vector or the bit vector b, selected according to a table, a configuration parameter, or a scheme, such as the scheme 408 of FIG. 4. The message vector m can be reshaped to a message matrix M by arranging the set of message sub-vectors as the rows of the message matrix, i.e. M=[m₀; m₁; m₂; m₃], which can be a convenient form for the processing by ANNs.

As shown in FIG. 6, the device may generate, using a common input linear layer 615, a set of message embedding vectors 620, denoted X. For example, X may be defined as

$${MW}_{3 \times d}^{( 0 )} + {1}_{4 \times 1} {b}_{1 \times d}^{( 0 )} = [ {x}_{0} ; {x}_{1} ; {x}_{2} ; {x}_{3} ] ,$$

where

$${W}_{3 \times d}^{( 0 )}$$

denotes the weights of the common input linear layer 615, and

$${b}_{1 \times d}^{( 0 )}$$

denotes the biases of the common input linear layer 615. The set of message embedding vectors 620 (denoted {xᵢ}) may correspond to the set of message sub-vectors 610. For example, the set of message embedding vectors 620 may be permutation-equivariant with regard to the set of message sub-vectors 610. This may be because, as shown in FIG. 6, the common input linear layer 615 is implemented with a same mathematical operation for each message sub-vector 610 input to the common input linear layer 615, such as using a same mathematical operation in terms of the values of weights and biases applied for processing of each message sub-vector 610. Thus, the common input linear layer 615 may provide permutation equivariance between the set of message sub-vectors 610 and the set of message embedding vectors 620. As shown in FIG. 6, in some aspects, the device may perform a normalization operation 625 (“LayerNorm”), such as a layer normalization operation or a batch normalization operation, on the set of message embedding vectors 620 to generate a set of normalized message embedding vectors 630, denoted

$${x}_{i}^{( 0 )} ,$$

where

$${X}^{( 0 )} = LayerNorm ( X ) = [ {x}_{0}^{( 0 )} ; {x}_{1}^{( 0 )} ; {x}_{2}^{( 0 )} ; {x}_{3}^{( 0 )} ] .$$

In some other aspects, the example 600 may omit the normalization operation 625.

Notably, positional embedding is not applied to the message embedding vectors 620. Since the positional embedding is not applied to the message embedding vectors 620, the output of the ANN 635 (described below) satisfies the permutation equivariance property. For example, suppose that the message vector 605 is given by m=[m₀, m₁, m₂, m₃], which is split into 4 message sub-vectors 610. Corresponding to the sequence of message sub-vectors [m₀, m₁, m₂, m₃], the sequence of codeword embedding vectors 640 is given by

$$[ {x}_{0}^{( L )} , {x}_{1}^{( L )} , {x}_{2}^{( L )} , {x}_{3}^{( L )} ] .$$

Now, if the message vector 605 (composed of message sub-vectors) were permuted to [m₃, m₂, m₀, m₁], the corresponding codeword embedding vectors 640 would be permuted in the same way to

$$[ {x}_{3}^{( L )} , {x}_{2}^{( L )} , {x}_{0}^{( L )} , {x}_{1}^{( L )} ] .$$

This permutation equivariance simplifies implementation of decoding of the codeword generated using the corresponding codeword embedding vectors 640, and specification of the codebook.

As shown in FIG. 6, the device may generate, using an ANN 635, a set of codeword embedding vectors 640, denoted by

$$\{ {x}_{i}^{( L )} \} .$$

### In FIG. 6,

$${X}^{( L )} = [ {x}_{0}^{( L )} ; {x}_{1}^{( L )} ; {x}_{2}^{( L )} ; {x}_{3}^{( L )} ] .$$

The ANN 635 may include or correspond to the ML model 406 of FIG. 4, and the set of codework embedding vectors 640 may include or correspond to the output tokens 426 of FIG. 4. The set of codeword embedding vectors 640 may correspond to the set of message embedding vectors 620 (or the set of normalized message embedding vectors 630). For example, the set of codeword embedding vectors 640 may be permutation-equivariant with regard to the set of message embedding vectors 620 and/or the set of normalized message embedding vectors 630. L may denote a number of layers of the ANN 635.

The ANN 635 may include a permutation-equivariant ANN. A permutation-equivariant ANN is an ANN of which an output of the ANN 635 is permutation-equivariant with an input of the ANN 635. For example, a permutation-equivariant ANN may include one or more transformer layers, a graph neural network, one or more self-attention layers, one or more layer normalization layers, one or more position-wise multi-layer perceptrons (MLPs), one or more average-pooling layers, or one or more max-pooling layers. The ANN 635 may be configured, using one or more of the above layers or networks, to provide permutation equivariance between the set of codeword embedding vectors 640 and the set of message embedding vectors 620 or normalized message embedding vectors 630. For example, the ANN 635 may be constructed using layers that satisfy the permutation equivariance property, meaning that the ANN 635 satisfies the permutation equivariance property. As one example, the ANN 635 may include Z transformer encoder layers. In some aspects, the device may perform a normalization operation 645 (“LayerNorm”), such as a layer normalization operation or a batch normalization operation, on the set of codeword embedding vectors 640 to generate a set of normalized codeword embedding vectors, denoted as

$${X}_{norm}^{( L )} = LayerNorm ( {X}^{( L )} )$$

(not shown in FIG. 6).

In some implementations, a transformer ANN structure makes use of attention mechanisms that may enable the model (such as the ANN 635) to process input sequences in a parallel and efficient manner. An attention mechanism allows the model to focus on different parts of the input sequence at different times. Attention mechanisms may be implemented using a series of layers (known as attention layers) to compute weighted sums of input features based on a similarity between different elements of the input sequence. A transformer ANN structure may include a series of feedforward ANN layers whose configurations may change in response to identifying non-linear relationships between the input and output sequences, which may also be referred to as a process of “learning” by the ANN layers. For example, a layer of the transformer ANN structure may include a self-attention layer and a multi-level perceptron. The output of a transformer ANN structure may be obtained by applying a linear transformation to the output of a final attention layer. A transformer ANN structure may be of particular use for tasks that involve sequence modeling, or other like processing.

The ANN 635 includes at least one first layer of artificial neurons to process input data and provide resulting first layer data via connections or “edges” to at least a portion of at least one second layer. The at least one second layer processes data received via edges and provides second layer output data via edges to at least a portion of at least one third layer. The at least one third layer processes data received via edges and provides third layer output data via edges (and so on) until a final layer is reached, where the final layer includes one or more neurons to provide output data.

As shown in FIG. 6, the device may generate, using a common output linear layer 650, a set of codeword sub-vectors 655, denoted {cᵢ} or collectively C. The device may generate the set of codeword sub-vectors 655 using the set of codeword embedding vectors 640 (or the set of normalized codeword embedding vectors) by inputting the set of codeword embedding vectors 640 or the set of normalized codeword embedding vectors to the common output linear layer 650. For example, C may be generated as

$${X}_{norm}^{( L )} {W}_{out} + {b}_{out} = [ {c}_{0} ; {c}_{1} ; {c}_{2} ; {c}_{3} ] ,$$

where Wₒᵤₜ denotes the weights of the common output linear layer 650, and bout denotes the biases of the common output linear layer 650. The set of codeword sub-vectors 655 may correspond to the set of message sub-vectors 610. For example, the set of codeword sub-vectors 655 may be permutation-equivariant with regard to the set of message sub-vectors 610 (and with regard to the set of codeword embedding vectors 640). This may be because, as shown in FIG. 6, the common output linear layer 650 uses a same mathematical operation for each codeword embedding vector 640 input to the common output linear layer 650, such as using a same mathematical operation in terms of the values of weights and biases applied for processing of each codeword embedding vector 640. Thus, the common output linear layer 650 may provide permutation equivariance between the set of codeword embedding vectors 640 and the set of codeword sub-vectors 655, thereby preserving the permutation equivariance of the message sub-vectors 610 and the codeword sub-vectors 655.

As shown in FIG. 6, in some aspects, the device may combine the set of codeword sub-vectors 655 to generate a codeword vector 660, denoted cᵤₙₙₒᵣₘ. For example, the device may concatenate the set of codeword sub-vectors 655 to form the codeword vector 660.

As shown in FIG. 6, in some aspects, the device may perform a power scaling operation 665. In some aspects, the power scaling operation 665 may include normalizing the unnormalized codeword vector 660 in accordance with a target transmit power parameter, such that a codeword vector 670 conforms to the target transmit power parameter (which may be beneficial to improve consistency of transmit power across codewords). For example, the power scaling operation 665 may scale each codeword vector cᵤₙₙₒᵣₘ in such a way that the average codeword power after power scaling meets the target transmit power parameter, for example, E[∥c∥²]=1, where E[·] represents an expectation operator. In that case, each codeword may be allowed to have a different power. Alternatively, the power scaling operation 665 may scale each codeword vector cᵤₙₙₒᵣₘ in such a way that each codeword has the same power, such as ∥c∥²=1. In some aspects, the power scaling operation 665 may include scaling a transmit power of the unnormalized codeword vector 660 in accordance with a scaling factor to generate the codeword vector 670, which may permit different codewords to have different transmit powers.

In some aspects, the device may generate a table, such as a lookup table. For example, the table may represent a codebook for a channel code of the example 600. The table may indicate combinations of message sub-vectors and a corresponding combination of codeword sub-vectors. The permutation-equivariant property of the message sub-vectors and the codeword sub-vectors may simplify implementation of the table for the specification of the codebook, and a decoder based on the table. For example, the permutation-equivariant property of the message sub-vectors may enable the codebook to be defined by specification of codeword sub-vectors (e.g., instead of specifying entire codeword vectors corresponding to entire message vectors). For example, the permutation-equivariant property may enable identification of a codeword sub-vector cᵢ corresponding to a particular message sub-vector mᵢ of a message vector m by reference to (1) the particular message sub-vector mᵢ, and (2) the set of remaining message sub-vectors {mⱼ}ⱼ\mᵢ of the message vector m. The backslash symbol denotes the set difference operation. Notably, the codeword sub-vector cᵢ does not depend on the order of message sub-vectors in the set {mⱼ}ⱼ\mᵢ, which reduces a size of the table to be specified, and the amount of computation needed for the decoding. For example, a size of the table may be represented by a first dimension and a second dimension, wherein the first dimension is given by

$${2}^{number of bits in {m}_{i}} \times ( \begin{matrix}{2}^{number of bits in {m}_{i}} + number of tokens - 2 \\ {2}^{number of bits in {m}_{i}} - 1\end{matrix} )$$

and the second dimension is given by (codeword length/number of tokens). Thus, the table is smaller than a table that explicitly defines mappings of all message vectors and codeword vectors by a factor of:

$${2}^{k - number of bits in {m}_{i}} \times number of tokens / ( \begin{matrix}{2}^{number of bits in {m}_{i}} + number of tokens - 2 \\ {2}^{number of bits in {m}_{i}} - 1\end{matrix} ) .$$

As a particular example, consider a codebook constructed with four codeword sub-vectors, for k=11 (11 bits per message vector) and n=32 (32 bits per code block), and consider a neural network f_{θ} that computes the codeword given by c=[c₀, c₁, c₂, c₃], where cᵢ is the codeword sub-vector corresponding to the message sub-vector mᵢ. Due to the permutation equivariance property of the proposed non-linear code construction, codeword sub-vector cᵢ can be identified by cᵢ=f_{θ}(mᵢ; {m₀, m₁, m₂, m₃}\mᵢ), where {m₀, m₁, m₂, m₃} denotes the set of message sub-vectors m₀, m₁, m₂ and m₃, where the order of the message sub-vectors does not matter. Thus, a size of the table does can be less than 2¹¹×32. For example, the table may define codeword sub-vectors for all combinations of m₀ and the set {m₁, m₂, m₃}, where mᵢ∈{−1, 1}³. The number of such combinations is smaller than 2^{k}. For example, assuming that there was no zero-padding, the number of such combinations is

$$8 * ( \begin{matrix}8 + 3 - 1 \\ 8 - 1\end{matrix} ) = 960.$$

Hence, the size of the table is 960×8, which is smaller than 2¹¹×32 by a factor of approximately 8.5.

An example of identifying a codeword vector using the table and a set of message sub-vectors is provided below. Each message sub-vector mᵢ of a message vector m that includes 3 message sub-vectors includes two bits. Each codeword sub-vector may include 8 real-valued symbols (not illustrated here). As shown, a row of the table indicates (1) a given message sub-vector (denoted mₐ to avoid confusion with indexes of message sub-vectors); (2) a set of remaining message sub-vectors of the message vector (denoted m_{b} and m_{c} to avoid confusion with indexes of message sub-vectors); and (3) a corresponding codeword sub-vector cₐ. Table 1 is an example of some rows of a table representing a codebook:

TABLE 1

| mₐ | {m_{b}, m_{c}} | cₐ |
|---|---|---|
| [+1, +1] | {[+1, −1], [−1, +1]} | α |
| [+1, −1] | {[+1, +1], [−1, +1]} | β |
| [−1, +1] | {[+1, +1], [+1, −1]} | γ |

If a transmitter is to transmit a bit vector [0, 0, 0, 1, 1, 0], the transmitter may first convert the bit vector to a message vector: [+1, +1, +1, −1, −1, +1]. The transmitter may then divide the message vector into three message sub-vectors: m₀=[+1, +1]; m₁=[+1, −₁]; m₂=[−1, +1]. To compute the codeword sub-vector corresponding to m₀, the transmitter may refer to a row of the table that indicates (1) m₀ (in this case, [+1, +1]), and (2) remaining message sub-vectors of the message vector (in this case, {[+1, −1], [−1, +1]}). Thus, the transmitter may refer to the first row of the table. Notably, the order of m_{b} and m_{c} in the message vector is not a factor in identifying the codeword sub-vector. Thus, the transmitter may identify α as a codeword sub-vector corresponding to m₀. To compute the codeword sub-vector corresponding to m₁, the transmitter may refer to a row of the table that indicates (1) m₁ (in this case, [+1, −1]), and (2) remaining message sub-vectors of the message vector (in this case, {[+1, +1], [−1, +1]}). Thus, the transmitter may refer to the second row of the table and may identify β as a codeword sub-vector corresponding to m₁. To compute the codeword sub-vector corresponding to m₂, the transmitter may refer to a row of the table that indicates (1) m₂ (in this case, [−1, +1]), and (2) remaining message sub-vectors of the message vector (in this case, {[+1, +1], [+1, −1]}). Thus, the transmitter may refer to the third row of the table and may identify γ as a codeword sub-vector corresponding to m₂. In this way, the transmitter may identify the codeword vector as [α, β, γ].

The ANN 635 or the AI/ML model may be implemented in various types of processing circuits along with memory and applicable instructions therein. For example, general-purpose hardware circuits, such as one or more CPUs, one or more GPUs, or suitable combinations thereof, may be employed to implement a model. In some implementations, one or more tensor processing units (TPUs), neural processing units (NPUs), or other special-purpose processors, FPGAs, ASICs, or the like may also be employed. In some implementations, the ANN 635 or the AI/ML model, such as the ML model 406 of FIG. 4, may be implemented by an NPU or a TPU embedded in a system-on-chip (SoC) along with other components, such as one or more CPUs, GPUs, or the like. An SoC includes several components manufactured on a shared semiconductor substrate. The NPU or TPU may be controlled by the one or more CPUs by configuring the AI/ML model implemented by the NPU or TPU with weights and biases, providing certain training data to the AI/ML model to configure the AI/ML model, or providing input data to the AI/ML model to obtain related inferences. The one or more CPUs may also receive the inferences and be configured to perform certain actions based on the inferences produced by the AI/ML model. The actions performed by the one or more CPUs may include sending commands to other components of the SoC or components external to the SoC to perform certain actions. For example, the CPU may send commands to an RF transceiver based on the outputs or inferences obtained from an AI/ML model to cause the RF transceiver to operate on a wireless network in accordance with the AI/ML model.

FIG. 7 is a diagram illustrating examples of generation of input tokens in accordance with the present disclosure. For example, the input tokens may include or correspond to the input tokens 424 generated in accordance with the message vector 422 and the scheme 408. The examples shown in FIG. 7 include a first example 700 associated with a first input token scheme, a second example 710 associated with a second input token scheme, a third example 720 associated with a third input token scheme, and a fourth example 730 associated with a fourth input token scheme. In some implementations, operations described with reference to FIG. 7 may be performed by the token generator 410 of FIG. 4. In FIG. 7, bits are represented as b with a subscript denoting different bits.

The first example 700 is associated with the message vector 422 having a bit payload of k=8 bits, and is associated with kₘₐₓ=11, token_size=3, and A=4. The first input token scheme indicates, when k is less than kₘₐₓ, to append the information bits of the message vector 422 with one or more zeros, where a number of zeros to be appended is determined as kₘₐₓ−k. Accordingly, in the first example 700, four zeros are appended to the message vector 422. The combination of the information bits of the message vector 422 and the appended one or more zeros may then be distributed among the input tokens 424, which in the first example 700 results in two input tokens with three information bits, one input token with two information bits and one zero, and one input token with three zeroes.

The second example 710 is associated with the message vector 422 having a bit payload of k=8 bits, and is associated with kₘₐₓ=11, token_size=3, and A=4. The second input token scheme indicates, when k is less than kₘₐₓ, to distribute the information bits of the message vector 422 among the input tokens 424 and set each remaining bit of each input token to zero. Accordingly, in the second example 710, for each input token of the input tokens 424, two respective information bits are selected from the message vector 422 and included in the input token, and a zero is also added for the remaining bit of the input token.

The third example 720 is associated with the message vector 422 having a bit payload of k=9 bits, and is associated with kₘₐₓ=11, token_size=3, and A=4. The third input token scheme indicates to assign ceil (k/A) bits from the message vector 422 to the initial input token of the input tokens 424, and to assign floor (k/A) bits and a zero to each of the remaining input tokens of the input tokens 424.

The fourth example 730 is associated with the message vector 422 having a bit payload of k=9 bits, and is associated with kₘₐₓ=11, token_size=3, and A=4. The third input token scheme indicates to assign floor (k/A) bits and a zero to each of the first three input tokens of the input tokens 424, and to assign ceil (k/A) bits from the message vector 422 to the last input token of the input tokens 424.

FIG. 8 is a diagram illustrating examples of generation of a codeword in accordance with the present disclosure. For example, the codeword may include or correspond to the codeword vector 428. The codeword may be generated in accordance with the output tokens 426. As described with reference to FIG. 8, different schemes may be used to modify the output tokens 426 to generate modified output tokens 808, which may be combined, such as concatenated, to generate the codeword vector 428. The examples of FIG. 8 include a first example 800 associated with a first output token scheme, a second example 810 associated with a second output token scheme, a third example 820 associated with a third output token scheme, and a fourth example 830 associated with a second output token scheme. In some implementations, operations described with reference to FIG. 8 may be performed by the encoder 411 or the codeword generator 412 of FIG. 4. In FIG. 8, coded symbols are represented as c with a subscript denoting different coded symbols.

The first example 800 is associated with the output tokens 426 having nₘₐₓ=32 coded symbols and A=4. The codeword vector 428 (not shown) has a number of coded symbols of n=20, and is generated as a combination (concatenation) of modified output tokens 808. The first output token scheme indicates, when n is less than nₘₐₓ, to collectively drop (remove) nₘₐₓ−n coded symbols from the output tokens 426 to generate the modified output tokens 808. For example, twelve coded symbols c₂₀-c₃₁ may be dropped and the remaining coded symbols may be distributed as groups of five coded symbols to each of the four modified output tokens 808.

The second example 810 is associated with the output tokens 426 having nₘₐₓ=32 coded symbols and A=4. The codeword vector 428 (not shown) has a number of coded symbols of n=20, and is generated as a combination (concatenation) of modified output tokens 808. The second output token scheme indicates, when n is less than nₘₐₓ, to retain one or more coded symbols from each output token of the output tokens 426 and to drop the remaining unretained coded symbols. For example, the number of coded symbols to retain from each output token may be determined as n/A, and the same number of coded symbols may be removed from each output token of the output tokens 426 to generate the modified output tokens 808. In the second example 810, for each output token of the output tokens 426, the respective first five coded symbols are retained and the respective last three coded symbols are dropped to generate the modified output tokens 808 that each include five respective coded symbols.

The third example 820 is associated with the output tokens 426 having nₘₐₓ=32 coded symbols and A=4. The codeword vector 428 (not shown) has a number of coded symbols of n=21, and is generated as a combination (concatenation) of modified output tokens 808. The third output token scheme indicates, when n is less than nₘₐₓ, to determine a first number of coded symbols to be removed from each of one or more first output tokens of the output tokens 426, and a second number of coded symbols to be removed from each of one or more second output tokens of the output tokens 426. As shown in the third example 820, for each of the first three output tokens of the output tokens 426, the first five coded symbols are retained and the remaining coded symbols are dropped from the respective output token. Additionally, for the last output token of the output tokens 426, the first six coded symbols are retained and the remaining coded symbols are dropped from the last output token. It is noted that although the third example 820 describes the last output token retaining more coded symbols to generate the modified output tokens 808, in other implementations, the third output token scheme may indicate a one or more output tokens of the output tokens 426 to retain the most coded symbols, one or more output tokens of the output tokens 426 to drop the most coded symbols, or a combination thereof.

The fourth example 830 is associated with the output tokens 426 having nₘₐₓ=32 coded symbols and A=4. The codeword vector 428 (not shown) has a number of coded symbols of n=64, and is generated as a combination (concatenation) of modified output tokens 808. A fourth output token scheme indicates, when n is greater than nₘₐₓ, to perform one or more a repetition operations in which one or more coded symbols from the output tokens 426 are copied and appended to the end of the output tokens 426 such that the modified output tokens 808 collectively have a number of coded symbols of n=64.

FIGS. 9-11 are flow diagrams illustrating example processes that support variable code-rate coding in accordance with the present disclosure. Operations of the processes of FIGS. 9-11 may be performed by a UE, such as the UE 115 described above with reference to FIGS. 1-4. For example, example operations (also referred to as “blocks”) of the processes of FIGS. 9-11 may enable the UE, such as a UE 1200 of FIG. 12, to perform variable code-rate coding, according to some aspects of the present disclosure.

FIG. 12 is a block diagram of an example UE 1200 that supports variable code-rate coding in accordance with the present disclosure. The UE 1200 may be configured to perform operations, including the blocks of one or more of the processes described with reference to FIGS. 9-11, to perform variable code-rate coding. In some implementations, the UE 1200 includes the structure, hardware, and components shown and described with reference to the UE 115 of FIGS. 1-4. For example, the UE 1200 includes the controller 280, which operates to execute code, such as logic or computer instructions, stored in the memory 282, as well as controlling the components of the UE 1200 that provide the features and functionality of the UE 1200. The UE 1200, under control of the controller 280, transmits and receives signals via wireless radios 1201a-r and the antennas 252a-r. The wireless radios 1201a-r include various components and hardware, as illustrated in FIG. 2 for the UE 115, including the modems 254a-r, the MIMO detector 256, the receive processor 258, the transmit processor 264, and the TX MIMO processor 266.

As shown, the memory 282 may include the communication manager 150 and an ML model 1205. Although illustrated in FIG. 12 as being included in the memory 282, in other implementations, the communication manager 150 may be a separate component of the UE 1200. The communication manager 150 may be configured to manage one or more operations supporting variable code-rate coding. For example, the communication manager 150 may include token generator logic 1202, encoder logic 1203, codeword generator logic 1204, or a combination thereof, to support variable code-rate coding. The token generator logic 1202 may include or correspond to the token generator 410 of FIG. 4. The token generator 1202 is configured to generate multiple input tokens, such as the input tokens 424, in accordance with a message vector, a scheme, or a combination thereof. The encoder logic 1203 may include or correspond to the encoder 411 of FIG. 4. The encoder logic 1203 is configured to generate multiple output tokens, such as the output tokens 426, in accordance with the multiple input tokens, the ML model 1205, or a combination thereof. The codeword generator logic 1204 may include or correspond to the codeword generator 412 of FIG. 4. The codeword generator logic 104 is configured to generate a codeword vector, such as the codeword vector 428, in accordance with the multiple output tokens, a scheme, or a combination thereof. The ML model 1205 may include or correspond to the ML model 406, the permutation equivariant ANN 520, the ANN 635, or the ML model 1205. The ML model 1205 is configured to be executed by an encoder, such as the encoder 411 or an encoder associated with the encoder logic 1203. The UE 1200 may receive signals from or transmit signals to one or more network nodes, such as the network node 105 of FIGS. 1-4.

Returning to a process 900 shown in FIG. 9, in block 902, the UE 1200 obtains a message vector including multiple bits. For example, the message vector may include or correspond to the message vector 422 or the message vector 605.

In block 904, the UE 1200 generates multiple input tokens in accordance with the message vector. For example, the multiple input tokens may include or correspond to the input tokens 424, the set of inputs 505, or the set of non-overlapping message sub-vectors 610. Each of one or more input tokens of the multiple input tokens may include at least one respective bit of the multiple bits of the message vector. In some implementations, at least a final input token of the multiple input tokens includes all zeros. In some other implementations, each input token of the multiple input tokens includes at least one respective bit of the multiple bits. In some such implementations, each input token of the multiple input tokens includes the same number of respective bits from the multiple bits.

In some implementations, the multiple input tokens include a sequence of non-overlapping vectors. Additionally, or alternatively, a total number of bits included in the multiple input tokens is associated with a number of input bits that an artificial neural network that generates output vectors is trained to receive. For example, the artificial neural network may include or correspond to the ML model 406, the permutation equivariant ANN 520, the ANN 635, or the ML model 1205. In some implementations, the artificial neural network is a permutation-equivariant artificial neural network. Additionally, or alternatively, the artificial neural network can include at least one of a transformer, a graph neural network, a self-attention layer, a layer normalization layer, a position-wise multi-layer perceptron, an average-pooling layer, or a max-pooling layer. In some implementations, the total number of bits included in the multiple input tokens may be greater than a total number of bits included in the message vector.

In some implementations, to generate the multiple input tokens, the UE 1200 divides the multiple bits of the message vector between the multiple input tokens. For example, the UE 1200 may divide the multiple bits between the multiple input tokens according to a scheme, such as the scheme 408. In some implementations, the UE 1200 obtains an indicator that indicates a number of input tokens of the multiple input tokens. For example, the indicator may be indicated by the scheme 408, the configuration data 470, or a combination thereof. In some implementations, the number of respective bits from the multiple bits that is included in each of the multiple input tokens is equal to a total number of bits included in the message vector divided by the number of input tokens included in the multiple input tokens.

In some implementations, the multiple input tokens are generated in accordance with a scheme, such as the scheme 408. The scheme may indicate one or more first input tokens of the multiple input tokens and one or more second input tokens of the multiple input tokens. Each first input token of the one or more first input tokens includes a first number of respective bits of the message vector and each second input token of the one or more second input tokens includes a second number of respective bits of the message vector. The second number may be different than the first number, such as by having a different value than the first number. In some implementations, the first number of bits is a ceiling of a number of the multiple bits divided by a total number of the multiple input tokens, and the second number is a floor of the number of the multiple bits divided by the total number of the multiple input tokens. In some such implementations, the one or more first input tokens includes a group of consecutive input tokens of the multiple input tokens. The one or more first input tokens and/or the group of consecutive input tokens may include one of an initial input token or a last input token of the multiple input tokens. For example, the last input token may include the first number of bits that is the ceiling of the number of the multiple bits divided by the total number of the multiple input tokens, as described with reference to the second example 720 of FIG. 7. Alternatively, the initial input token may include the first number of bits that is the ceiling of the number of the multiple bits divided by the total number of the multiple input tokens, as described with reference to the third example 730 of FIG. 7.

In block 906, the UE 1200 generates, in accordance with the multiple input tokens and using the artificial neural network, multiple output tokens. The multiple output tokens may include or correspond to the output tokens 426, the set of outputs 525, or the set of codeword sub-vectors 655. The multiple output tokens may be permutation equivariant relative to the multiple input tokens. In some implementations, to generate the multiple output tokens, the UE 1200 may use an encoder, such as the encoder 411.

In some implementations, to generate the multiple output tokens, the UE 1200 may use an encoder, such as the encoder 411. Additionally, or alternatively, to generate the multiple output tokens, the UE 1200 may generate, in accordance with one or more first linear projection operations, multiple input embedding vectors corresponding to the multiple input tokens. The one or more first linear projection operations and the multiple input embedding vectors may include or correspond to the common input linear layer 615 and the set of message embedding vectors 620, respectively. The UE 1200 may generate, using the artificial neural network, multiple output embedding vectors corresponding to the multiple input embedding vectors. For example, the multiple output embedding vectors may be generated by a transformer encoder or an attention-only encoder of the artificial neural network. The multiple output embedding vector may include or correspond to the set of codeword embedding vectors 640. The UE 1200 can generate, using the multiple output embedding vectors and in accordance with one or more second linear projection operations, the multiple output tokens. The one or more second linear projection operations may include or correspond to the common output linear layer 650.

In block 908, the UE 1200 transmits the codeword vector that is generated in accordance with the multiple output tokens. Additionally, or alternatively, the UE may transmit a communication in accordance with the codeword vector. For example, the communication may include or correspond to the communication 472. Additionally, or alternatively, the codeword vector may include or correspond to the codeword vector 428. In some implementations, the UE 1200 generates the codeword vector in accordance with the multiple output tokens, such as without modifying the output tokens.

In some implementations, the UE 1200 modifies the multiple output tokens to include a total number of symbols that is the same as a total number of symbols of the codeword vector. The modified multiple output tokens may include or correspond to the modified output tokens 808. The modified multiple output tokens may be permutation equivariant relative to the multiple input tokens. Additionally, or alternatively, the codeword vector may further be generated in accordance with the modified multiple output tokens.

Referring to FIG. 10, for a process 1000, in block 1002, the UE 1200 obtains a message vector including multiple bits. For example, the message vector may include or correspond to the message vector 422 or the message vector 605.

In block 1004, the UE 1200 generates multiple input tokens in accordance with the message vector. For example, the multiple input tokens may include or correspond to the input tokens 424, the set of inputs 505, or the set of non-overlapping message sub-vectors 610.

In block 1006, the UE 1200 generates, in accordance with the multiple input tokens and using an artificial neural network, multiple output tokens. For example, the artificial neural network may include or correspond to the ML model 406, the permutation equivariant ANN 520, the ANN 635, or the ML model 1205. The multiple output tokens may include or correspond to the output tokens 426, the set of outputs 525, or the set of codeword sub-vectors 655. In some implementations, the artificial neural network is a permutation-equivariant artificial neural network. Additionally, or alternatively, the artificial neural network can include at least one of a transformer, a graph neural network, a self-attention layer, a layer normalization layer, a position-wise multi-layer perceptron, an average-pooling layer, or a max-pooling layer. In some implementations, a total number of symbols included in the multiple output tokens is equal to a number of output symbols that the artificial neural network is trained to output. The multiple output tokens may be permutation equivariant relative to the multiple input tokens.

In some implementations, to generate the multiple output tokens, the UE 1200 may use an encoder, such as the encoder 411. Additionally, or alternatively, to generate the multiple output tokens, the UE 1200 may generate, in accordance with one or more first linear projection operations, multiple input embedding vectors corresponding to the multiple input tokens. The one or more first linear projection operations and the multiple input embedding vectors may include or correspond to the common input linear layer 615 and the set of message embedding vectors 620, respectively. The UE 1200 may generate, using the artificial neural network, multiple output embedding vectors corresponding to the multiple input embedding vectors. For example, the multiple output embedding vectors may be generated by a transformer encoder or an attention-only encoder of the artificial neural network. The multiple output embedding vector may include or correspond to the set of codeword embedding vectors 640. The UE 1200 can generate, using the multiple output embedding vectors and in accordance with one or more second linear projection operations, the multiple output tokens. The one or more second linear projection operations may include or correspond to the common output linear layer 650.

In block 1008, the UE 1200 modifies the multiple output tokens to include a total number of symbols that is the same as a total number of symbols of a codeword vector. The modified multiple output tokens may include or correspond to the modified output tokens 808. The modified multiple output tokens may be permutation equivariant relative to the multiple input tokens. In some implementations, the UE 1200 obtains an indicator that indicates the total number of symbols of the codeword vector. For example, the indicator may include or correspond to the scheme 408, the configuration data 470, or a combination thereof.

In some implementations, the UE 1200 determines whether the total number of symbols included in the multiple output tokens is equal to the total number of symbols of the codeword vector. In accordance with a determination that the total number of symbols of the codeword vector is less than the total number of symbols included in the multiple output tokens, the UE 1200 may modify the multiple output tokens to remove, for at least one output token of the multiple output tokens, at least one symbol from the at least one output token, as described at least with reference to the examples 800, 810, 820, and 830 of FIG. 8. In some implementations, the at least one output token includes a final output token of the multiple output tokens. In some implementations, to modify the multiple output tokens, the UE 1200 removes the same number of symbols from each output token of the multiple output tokens, as described at least with reference to the example 810 of FIG. 8. In other implementations, to modify the multiple output tokens, the UE 1200, for each output token of one or more first output tokens of the multiple output tokens, removes a first number of symbols from the output token, and for each output token of one or more second output tokens of the multiple output tokens, removes a second number of symbols from the output token, as described at least with reference to the examples 820 and 830 of FIG. 8. The second number of symbols may be different from the first number of symbols.

In some other implementations, in accordance with a determination that the total number of symbols of the codeword vector is greater than the total number of symbols included in the multiple output tokens, the UE 1200 may perform a repetition operation using at least a portion of at least one output token of the multiple output tokens to modify the multiple output tokens to include the total number of symbols of the codeword vector, as described at least with reference to the example 840 of FIG. 8.

In block 1010, the UE 1200 generates the codeword vector in accordance with the modified multiple output tokens. For example, the codeword vector may include or correspond to the codeword vector 428 or the codeword vector 660. In some implementations, to generate the codeword vector, the UE 1200 concatenates the modified multiple output tokens.

In block 1012, the UE 1200 transmits the codeword vector. Additionally, or alternatively, the UE 1200 may transmit a communication in accordance with the codeword vector. For example, the communication may include or correspond to the communication 472.

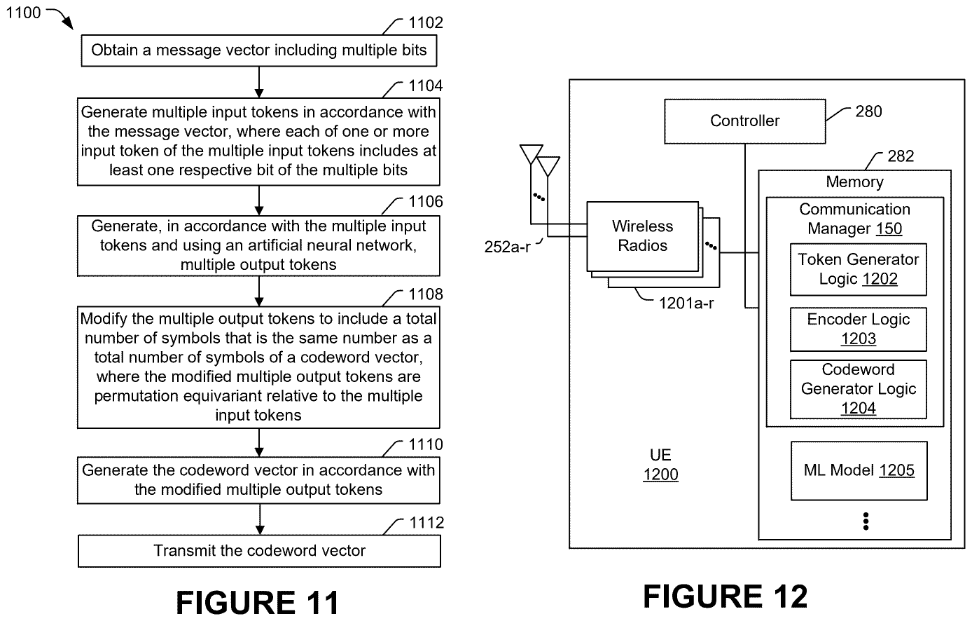

Referring to FIG. 11, for a process 1100, in block 1102, the UE 1200 obtains a message vector including multiple bits. For example, the message vector may include or correspond to the message vector 422 or the message vector 605.

In block 1104, the UE 1200 generates multiple input tokens in accordance with the message vector. For example, the multiple input tokens may include or correspond to the input tokens 424, the set of inputs 505, or the set of non-overlapping message sub-vectors 610. Each of one or more input tokens of the multiple input tokens may include at least one respective bit of the multiple bits of the message vector. In some implementations, at least a final input token of the multiple input tokens includes all zeros. In some other implementations, each input token of the multiple input tokens includes at least one respective bit of the multiple bits. In some such implementations, each input token of the multiple input tokens includes the same number of respective bits from the multiple bits.

In block 1106, the UE 1200 generates, in accordance with the multiple input tokens and using an artificial neural network, multiple output tokens. For example, the artificial neural network may include or correspond to the ML model 406, the permutation equivariant ANN 520, the ANN 635, or the ML model 1205. In some implementations, the artificial neural network is a permutation-equivariant artificial neural network. Additionally, or alternatively, the artificial neural network can include at least one of a transformer, a graph neural network, a self-attention layer, a layer normalization layer, a position-wise multi-layer perceptron, an average-pooling layer, or a max-pooling layer. The multiple output tokens may include or correspond to the output tokens 426, the set of outputs 525, or the set of codeword sub-vectors 655. The multiple output tokens may be permutation equivariant relative to the multiple input tokens.

In some implementations, to generate the multiple output tokens, the UE 1200 may use an encoder, such as the encoder 411. Additionally, or alternatively, to generate the multiple output tokens, the UE 1200 may generate, in accordance with one or more first linear projection operations, multiple input embedding vectors corresponding to the multiple input tokens. The one or more first linear projection operations and the multiple input embedding vectors may include or correspond to the common input linear layer 615 and the set of message embedding vectors 620, respectively. The UE 1200 may generate, using the artificial neural network, multiple output embedding vectors corresponding to the multiple input embedding vectors. For example, the multiple output embedding vectors may be generated by a transformer encoder or an attention-only encoder of the artificial neural network. The multiple output embedding vector may include or correspond to the set of codeword embedding vectors 640. The UE 1200 can generate, using the multiple output embedding vectors and in accordance with one or more second linear projection operations, the multiple output tokens. The one or more second linear projection operations may include or correspond to the common output linear layer 650.

In block 1108, the UE 1200 modifies the multiple output tokens to include a total number of symbols that is the same number as a total number of symbols of a codeword vector. The modified multiple output tokens may include or correspond to the modified output tokens 808. The modified multiple output tokens may be permutation equivariant relative to the multiple input tokens.

In block 1110, the UE 1200 generates the codeword vector in accordance with the modified multiple output tokens. For example, the codeword vector may include or correspond to the codeword vector 428 or the codeword vector 660. In some implementations, to generate the codeword vector, the UE 1200 concatenates the modified multiple output tokens.

In block 1112, the UE 1200 transmits the codeword vector. Additionally, or alternatively, the UE 1200 may transmit a communication in accordance with the codeword vector. For example, the communication may include or correspond to the communication 472.

It is noted that one or more blocks (or operations) described with reference to FIGS. 9-11 may be combined with one or more blocks (or operations) described with reference to another of the figures. For example, one or more blocks (or operations) of FIG. 9 may be combined with one or more blocks (or operations) of FIG. 10. As another example, one or more blocks (or operations) of FIG. 9 may be combined with one or more blocks (or operations) of FIG. 11. As another example, one or more blocks (or operations) of FIG. 10 may be combined with one or more blocks (or operations) of FIG. 11. As another example, one or more blocks associated with FIG. 9-11 may be combined with one or more blocks (or operations) associated with FIGS. 1-8. Additionally, or alternatively, one or more operations described above with reference to FIGS. 1-8 may be combined with one or more operations described with reference to FIG. 12.

In the following, further examples are described to facilitate the understanding of the disclosure.

According to Example 1, a wireless communication device includes a processing system that includes one or more processors and one or more memories that store code and are coupled with the one or more processors, the processing system configured to cause the wireless communication device to: obtain a message vector including multiple bits; generate multiple input tokens in accordance with the message vector, where each of one or more input tokens of the multiple input tokens includes at least one respective bit of the multiple bits; generate, in accordance with the multiple input tokens and using an artificial neural network, multiple output tokens, where the multiple output tokens are permutation equivariant relative to the multiple input tokens; and transmit a codeword vector generated in accordance with the multiple output tokens.

Example 2 includes the wireless communication device of Example 1, where: a total number of bits included in the multiple input tokens is associated with a number of input bits the artificial neural network is trained to receive, and the total number of bits included in the multiple input tokens is greater than a total number of bits included in the message vector, and, to generate the multiple input tokens, the processing system is configured to cause the wireless communication device to divide multiple bits of the message vector between the multiple input tokens, the multiple input tokens including a sequence of non-overlapping vectors.

Example 3 includes the wireless communication device of Example 1 or Example 2, where the processing system is configured to cause the wireless communication device to: generate, in accordance with one or more first linear projection operations, multiple input embedding vectors corresponding to the multiple input tokens; generate, by a transformer encoder using the artificial neural network, multiple output embedding vectors corresponding to the multiple input embedding vectors; and generate, using the multiple output embedding vectors and in accordance with one or more second linear projection operations, the multiple output tokens.

Example 4 includes the wireless communication device of any of Examples 1 to 3, where: the multiple input tokens include a sequence of non-overlapping vectors, and at least a final input token of the multiple input tokens includes all zeros.

Example 5 includes the wireless communication device of any of Examples 1 to 3, where each input token of the multiple input tokens includes the same number of respective bits from the multiple bits.

Example 6 includes the wireless communication device of any of Examples 1 to 3, where the processing system is configured to cause the wireless communication device to: obtain an indicator that indicates a number of input tokens of the multiple input tokens, and where the number of respective bits from the multiple bits is equal to a total number of bits included in the message vector divided by the number of input tokens included in the multiple input tokens.

Example 7 includes the wireless communication device of any of Examples 1 to 3, where the multiple input tokens are generated in accordance with a scheme that indicates: one or more first input tokens of the multiple input tokens, each first input token of the one or more first input tokens includes a first number of respective bits of the message vector, and one or more second input tokens of the multiple input tokens, each second input token of the one or more second input tokens includes a second number of respective bits of the message vector, the second number being different than the first number.

Example 8 includes the wireless communication device of Example 7, where: the first number of bits is a ceiling of a number of the multiple bits divided by a total number of the multiple input tokens, and the second number is a floor of the number of the multiple bits divided by the total number of the multiple input tokens.

Example 9 includes the wireless communication device of Example 7, where: the one or more first input tokens includes a group of consecutive input tokens of the multiple input tokens, and the group of consecutive input tokens includes one of an initial input token or a last input token of the multiple input tokens.

Example 10 includes the wireless communication device of any of Examples 1 to 9, where: the processing system is configured to cause the wireless communication device to modify the multiple output tokens to include a total number of symbols that is the same as a total number of symbols of the codeword vector, where the modified multiple output tokens are permutation equivariant relative to the multiple input tokens, and the codeword vector is further generated in accordance with the modified multiple output tokens.

According to Example 11, a wireless communication device includes a processing system that includes one or more processors and one or more memories that store code and are coupled with the one or more processors, the processing system configured to cause the wireless communication device to: obtain a message vector including multiple bits; generate multiple input tokens in accordance with the message vector; generate, in accordance with the multiple input tokens and using an artificial neural network, multiple output tokens; modify the multiple output tokens to include a total number of symbols that is the same as a total number of symbols of a codeword vector, where the modified multiple output tokens are permutation equivariant relative to the multiple input tokens; generate the codeword vector in accordance with the modified multiple output tokens; and transmit the codeword vector.

Example 12 includes the wireless communication device of Example 11, where: a total number of symbols included in the multiple output tokens is equal to a number of output symbols that the artificial neural network is trained to output, and to generate the codeword vector, the processing system is configured to cause the wireless communication device to concatenate the modified multiple output tokens.

Example 13 includes the wireless communication device of Example 11 or Example 12, where the processing system is configured to cause the wireless communication device to: obtain an indicator that indicates the total number of symbols of the codeword vector; modify, in accordance with a determination that the total number of symbols of the codeword vector is less than the total number of symbols included in the multiple output tokens, the multiple output tokens to remove, for at least one output token of the multiple output tokens, at least one symbol from the at least one output token; and combine each output token of the modified multiple output tokens to generate the codeword vector.

Example 14 includes the wireless communication device of Example 13, where, to modify the multiple output tokens, the processing system is configured to cause the wireless communication device to remove the same number of symbols from each output token of the multiple output tokens.

Example 15 includes the wireless communication device of Example 13, where, to modify the multiple output tokens, the processing system is configured to cause the wireless communication device to: for each output token of one or more first output tokens of the multiple output tokens, remove a first number of symbols from the output token; and for each output token of one or more second output tokens of the multiple output tokens, remove a second number of symbols from the output token, and where the second number of symbols is different from the first number of symbols.

Example 16 includes the wireless communication device of Example 13, where the at least one output token includes a final output token of the multiple output tokens.

Example 17 includes the wireless communication device of Example 11, where the processing system is configured to cause the wireless communication device to: obtain an indicator that indicates the total number of symbols of the codeword vector; and in accordance with the total number of symbols of the codeword vector being greater than the total number of symbols included in the multiple output tokens, perform a repetition operation using at least a portion of at least one output token of the multiple output tokens to modify the multiple output tokens to include the total number of symbols of the codeword vector.

According to Example 18, a method of wireless communication by a wireless communication device includes: obtaining a message vector including multiple bits, the multiple bits including a number of bits; generating multiple input tokens in accordance with the message vector, where each of one or more input token of the multiple input tokens includes at least one respective bit of the multiple bits; generating, in accordance with the multiple input tokens and using an artificial neural network, multiple output tokens; modifying the multiple output tokens to include a total number of symbols that is the same number as a total number of symbols of a codeword vector, where the modified multiple output tokens are permutation equivariant relative to the multiple input tokens; generating the codeword vector in accordance with the modified multiple output tokens; and transmitting the codeword vector.

Example 19 includes the method of Example 18, where generating the multiple output tokens includes: generating, in accordance with one or more first linear projection operations, multiple input embedding vectors corresponding to the multiple input tokens; generating, using the artificial neural network, multiple output embedding vectors corresponding to the multiple input embedding vectors; and generating, using the multiple output embedding vectors and in accordance with one or more second linear projection operations, the multiple output tokens.

Example 20 includes the method of Example 18 or Example 19, where: generating the codeword vector includes concatenating the modified multiple output tokens, and the artificial neural network is a permutation-equivariant artificial neural network and includes at least one of a transformer, a graph neural network, a self-attention layer, a layer normalization layer, a position-wise multi-layer perceptron, an average-pooling layer, or a max-pooling layer.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-12 include processors, electronics devices, hardware devices, electronics components, logical circuits, memories, software codes, firmware codes, among other examples, or any combination thereof. In addition, features discussed herein may be implemented via specialized processor circuitry, via executable instructions, or combinations thereof.

Those of skill would further appreciate that the various illustrative logics, logical blocks, modules, circuits, and algorithm processes described in connection with the disclosure herein may be implemented as electronic hardware, computer software, or combinations of both. To clearly illustrate this interchangeability of hardware and software, various illustrative components, blocks, modules, circuits, and processes have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

As used herein, the term “component” is intended to be broadly construed as hardware or a combination of hardware and at least one of software or firmware. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include random access memory (RAM), read-only memory (ROM), electronically erasable programable ROM (EEPROM), compact disc (CD) ROM (CD-ROM), or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product or a computer-readable storage device.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flow diagram. However, other operations that are not depicted can be incorporated in the example processes that are schematically illustrated. For example, one or more additional operations can be performed before, after, simultaneously with, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, some other implementations are within the scope of the following claims. In some cases, the actions recited in the claims can be performed in a different order and still achieve desirable results.

As used herein, including in the claims, the term “or,” when used in a list of two or more items, means that any one of the listed items can be employed by itself, or any combination of two or more of the listed items can be employed. For example, if a composition is described as containing components A, B, or C, the composition can contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples. Such a threshold may be a single value or a range of values. As an illustrative example, a value may satisfy a threshold range of values if the value is greater than or equal to each of the threshold values included within in the threshold range of values.

No element, act, or instruction used herein should be construed as critical or essential unless explicitly described as such. Also, as used herein, the articles “a” and “an” are intended to include one or more items and may be used interchangeably with “one or more.” It should be understood that “one or more” is equivalent to “at least one.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based on or otherwise in association with” unless explicitly stated otherwise. Similarly, the phrase “in accordance with” is intended to mean “based on or otherwise in association with” unless explicitly stated otherwise.

The previous description of the disclosure is provided to enable any person skilled in the art to make or use the disclosure. Various modifications to the implementations described in this disclosure may be readily apparent to those skilled in the art, and the generic principles defined herein may be applied to other variations without departing from the scope of this disclosure. Thus, the disclosure is not intended to be limited to the examples and designs described herein but is to be accorded the widest scope consistent with the principles and novel features disclosed herein.

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set.

What is claimed is:

1. A wireless communication device, comprising:
a processing system that includes one or more processors and one or more memories that store code and are coupled with the one or more processors, the processing system configured to cause the wireless communication device to:
obtain a message vector including multiple bits;
generate multiple input tokens in accordance with the message vector, wherein each of one or more input tokens of the multiple input tokens includes at least one respective bit of the multiple bits;
generate, in accordance with the multiple input tokens and using an artificial neural network, multiple output tokens, wherein the multiple output tokens are permutation equivariant relative to the multiple input tokens; and
transmit a codeword vector generated in accordance with the multiple output tokens.

2. The wireless communication device of claim 1, wherein:
a total number of bits included in the multiple input tokens is associated with a number of input bits the artificial neural network is trained to receive,
the total number of bits included in the multiple input tokens is greater than a total number of bits included in the message vector, and
to generate the multiple input tokens, the processing system is configured to cause the wireless communication device to divide multiple bits of the message vector between the multiple input tokens, the multiple input tokens including a sequence of non-overlapping vectors.

3. The wireless communication device of claim 1, wherein the processing system is configured to cause the wireless communication device to:
generate, in accordance with one or more first linear projection operations, multiple input embedding vectors corresponding to the multiple input tokens;
generate, by a transformer encoder using the artificial neural network, multiple output embedding vectors corresponding to the multiple input embedding vectors; and
generate, using the multiple output embedding vectors and in accordance with one or more second linear projection operations, the multiple output tokens.

4. The wireless communication device of claim 1, wherein:
the multiple input tokens include a sequence of non-overlapping vectors, and
at least a final input token of the multiple input tokens includes all zeros.

5. The wireless communication device of claim 1, wherein each input token of the multiple input tokens includes the same number of respective bits from the multiple bits.

6. The wireless communication device of claim 1, wherein:
the processing system is configured to cause the wireless communication device to obtain an indicator that indicates a number of input tokens of the multiple input tokens, and
the number of respective bits from the multiple bits is equal to a total number of bits included in the message vector divided by the number of input tokens included in the multiple input tokens.

7. The wireless communication device of claim 1, wherein the multiple input tokens are generated in accordance with a scheme that indicates:
one or more first input tokens of the multiple input tokens, each first input token of the one or more first input tokens includes a first number of respective bits of the message vector, and
one or more second input tokens of the multiple input tokens, each second input token of the one or more second input tokens includes a second number of respective bits of the message vector, the second number being different than the first number.

8. The wireless communication device of claim 7, wherein:
the first number of bits is a ceiling of a number of the multiple bits divided by a total number of the multiple input tokens, and
the second number is a floor of the number of the multiple bits divided by the total number of the multiple input tokens.

9. The wireless communication device of claim 7, wherein:
the one or more first input tokens includes a group of consecutive input tokens of the multiple input tokens, and
the group of consecutive input tokens includes one of an initial input token or a last input token of the multiple input tokens.

10. The wireless communication device of claim 1, wherein:
the processing system is configured to cause the wireless communication device to modify the multiple output tokens to include a total number of symbols that is the same as a total number of symbols of the codeword vector, wherein the modified multiple output tokens are permutation equivariant relative to the multiple input tokens, and
the codeword vector is further generated in accordance with the modified multiple output tokens.

11. A wireless communication device, comprising:
a processing system that includes one or more processors and one or more memories that store code and are coupled with the one or more processors, the processing system configured to cause the wireless communication device to:
obtain a message vector including multiple bits;
generate multiple input tokens in accordance with the message vector;
generate, in accordance with the multiple input tokens and using an artificial neural network, multiple output tokens;
modify the multiple output tokens to include a total number of symbols that is the same as a total number of symbols of a codeword vector, wherein the modified multiple output tokens are permutation equivariant relative to the multiple input tokens;
generate the codeword vector in accordance with the modified multiple output tokens; and
transmit the codeword vector.

12. The wireless communication device of claim 11, wherein:
a total number of symbols included in the multiple output tokens is equal to a number of output symbols that the artificial neural network is trained to output, and
to generate the codeword vector, the processing system is configured to cause the wireless communication device to concatenate the modified multiple output tokens.

13. The wireless communication device of claim 11, wherein the processing system is configured to cause the wireless communication device to:
obtain an indicator that indicates the total number of symbols of the codeword vector;
modify, in accordance with a determination that the total number of symbols of the codeword vector is less than the total number of symbols included in the multiple output tokens, the multiple output tokens to remove, for at least one output token of the multiple output tokens, at least one symbol from the at least one output token; and
combine each output token of the modified multiple output tokens to generate the codeword vector.

14. The wireless communication device of claim 13, wherein, to modify the multiple output tokens, the processing system is configured to cause the wireless communication device to remove the same number of symbols from each output token of the multiple output tokens.

15. The wireless communication device of claim 13, wherein, to modify the multiple output tokens, the processing system is configured to cause the wireless communication device to:
for each output token of one or more first output tokens of the multiple output tokens, remove a first number of symbols from the output token; and
for each output token of one or more second output tokens of the multiple output tokens, remove a second number of symbols from the output token, and wherein the second number of symbols is different from the first number of symbols.

16. The wireless communication device of claim 13, wherein the at least one output token includes a final output token of the multiple output tokens.

17. The wireless communication device of claim 11, wherein the processing system is configured to cause the wireless communication device to:
obtain an indicator that indicates the total number of symbols of the codeword vector; and
in accordance with the total number of symbols of the codeword vector being greater than the total number of symbols included in the multiple output tokens, perform a repetition operation using at least a portion of at least one output token of the multiple output tokens to modify the multiple output tokens to include the total number of symbols of the codeword vector.

18. A method of wireless communication by a wireless communication device, comprising:
obtaining a message vector including multiple bits;
generating multiple input tokens in accordance with the message vector, wherein each of one or more input token of the multiple input tokens includes at least one respective bit of the multiple bits;
generating, in accordance with the multiple input tokens and using an artificial neural network, multiple output tokens;
modifying the multiple output tokens to include a total number of symbols that is the same number as a total number of symbols of a codeword vector, wherein the modified multiple output tokens are permutation equivariant relative to the multiple input tokens;
generating the codeword vector in accordance with the modified multiple output tokens; and
transmitting the codeword vector.

19. The method of claim 18, wherein generating the multiple output tokens includes:
generating, in accordance with one or more first linear projection operations, multiple input embedding vectors corresponding to the multiple input tokens;
generating, using the artificial neural network, multiple output embedding vectors corresponding to the multiple input embedding vectors; and
generating, using the multiple output embedding vectors and in accordance with one or more second linear projection operations, the multiple output tokens.

20. The method of claim 18, wherein:
generating the codeword vector includes concatenating the modified multiple output tokens, and
the artificial neural network is a permutation-equivariant artificial neural network and includes at least one of a transformer, a graph neural network, a self-attention layer, a layer normalization layer, a position-wise multi-layer perceptron, an average-pooling layer, or a max-pooling layer.
